(19) United States
(12) Patent Application Publication
(10) Pub. No.: US 2014/0374143 A1
(43) Pub. Date: Dec. 25, 2014

(54) DRY FILM, LAYERED STRUCTURE, PRINTED WIRING BOARD, AND PROCESS FOR PRODUCING LAYERED STRUCTURE

(71) Applicant: TAIYO INK MFG. CO., LTD., Hiki-gun, Saitama (JP)

(72) Inventors: Daichi Okamoto, Hiki-gun (JP); Nobuhito Ito, Hiki-gun (JP); Shoji Minegishi, Hiki-gun (JP)

(73) Assignee: TAIYO INK MFG. CO., LTD., Hiki-gun, Saitaman (JP)

(21) Appl. No.: 14/369,356

(22) PCT Filed: Dec. 25, 2012
(86) PCT No.: PCT/JP2012/083527

§ 371 Date: Jun. 27, 2014

(30) Foreign Application Priority Data
Dec. 27, 2011 (JP) 2011-285640

(51) Int. Cl. H05K 1/02; G03F 7/20; G03F 7/09

(52) U.S. Cl. CPC H05K 1/02; G03F 7/094; G03F 7/20; H05K 2201/09009
USPC 174/250; 430/270.1; 430/325

(57) ABSTRACT

The present invention provides a dry film which can obtain a solder resist having an excellent resolution while maintaining various characteristics including PCT resistance, a laminated structure such as a printed writing board, and a method of producing the laminated structure.

A dry film comprising: a film; and a photosensitive resin layer formed on the film, wherein the absorption coefficient (α) of the photosensitive resin layer at a wavelength of 365 nm has an increase gradient or a decrease gradient from a surface of the photosensitive resin layer toward a surface of the film.

### TECHNICAL FIELD

The present invention relates to a dry film which can be used for producing a solder resist and an interlayer resin insulation layer, a laminated structure such as a printed writing board, and a method of producing the laminated structure.

### BACKGROUND ART

In recent years, in response to high densification of the printed writing board associated with decreasing weight and size of electronic equipments, there is also an increasing demand for good workability and high performance in a solder resist. Furthermore, in associated with miniaturization, reduction in weight and high performance of electronic equipments, miniaturization of a semiconductor package having a plurality of pins is put in practical use and the mass production thereof is developed. In response to such high densification of the printed writing board, the IC packages called BGA (ball grid array), CSP (chip scale package), etc. are recently used instead of the IC packages called QFP (quad flat-pack package), SOP (small outline package), etc. As a solder resist used for such a package substrate or a printed writing board to be mounted in an automobile, various photosensitive resin compositions are heretofore proposed (for example, see Patent Document 1).

In packages having a solder resist, since a substrate and a solder resist are heated at the time of sealing an IC chip and driving the IC, they are liable to cause cracks and peeling of the solder resist due to the difference in the expansion coefficient between the substrate and the solder resist. Therefore, for the purpose of suppressing the occurrence of cracks and peeling of the solder resist which are produced at the time of a pressure cooker test (hereafter abbreviated as “PCT”) or thermal cycling, the incorporation of an inorganic filler into a photosensitive resin composition that forms the solder resist is widely performed conventionally so that the linear thermal expansion coefficient of the solder resist corresponds to that of the substrate used as a base of the solder resist as far as possible.

Since an inorganic filler generally exhibits high opacifying effects or ultraviolet absorbing power depending on a material, when a photosensitive resin composition contains a large amount of inorganic filler, there is a problem of decreasing the substantial dose of ultraviolet irradiation to a photosensitive resin and thus easily causing undercure thereof. In order to solve such a problem, there is proposed to prepare a photosensitive resin layer as a two-layer structure; the first photosensitive resin layer containing an inorganic filler being formed on a substrate, and the second photosensitive resin layer that does not contain an inorganic filler being laminated thereon (see Patent Document 2). According to the photosensitive resist as described in Patent Document 2, such a two-layer structure aims at allowing patterning with a small dose of ultraviolet irradiation, as compared with the case where only the photosensitive resin layer containing the inorganic filler is patterned as being conventionally performed. That is, since the second photosensitive resin layer will not suffer from the interception or absorption of ultraviolet rays by the inorganic filler, the substantial dose of ultraviolet irradiation will increase even with the same irradiation dose and the sensitivity as a whole will be seemingly improved.

### RELATED ART DOCUMENTS

### Patent Documents

[Patent Document 1] Japanese Unexamined Patent Application Publication No. S61-243869 (Claims)

[Patent Document 2] Japanese Unexamined Patent Application Publication No. H10-207046 (Claims)

### SUMMARY OF THE INVENTION

### Problems to be Solved by the Invention

When a two-layer structure is prepared as described above by forming the first photosensitive resin layer containing an inorganic filler on a substrate and laminating thereon the second photosensitive resin layer that does not contain an inorganic filler, however, a light passing through the second photosensitive resin layer reaches the first photosensitive resin layer when irradiating the light. Since the first photosensitive resin layer also exhibits the effect of light shielding by an inorganic filler, the amount of radial generated from the second photosensitive resin layer is much larger than that of radial generated from the first photosensitive resin layer. Thus, an excessive photo-curing reaction, that is halation, is caused in the second photosensitive resin layer.

When a recessed part such as a via hole is formed by exposing and developing such the first photosensitive resin layer and second photosensitive resin layer, the recessed part is a reversed taper structure (see FIG. 2(B)).

The reversed taper structure causes poor adhesion of a solder and easy solder peeling. That is, Patent Document 2 discloses that there is a problem that a solder resist having poor resolution at the time of patterning is obtained.

Therefore, it is an object of the present invention to solve the problems of the prior art mentioned above and to provide a dry film which can obtain a solder resist having an excellent resolution while maintaining various characteristics including PCT resistance, a laminated structure such as a printed writing board, and a method of producing the laminated structure.

### Means for Solving the Problems

The present inventors intensively studied in order to solve the above-described problems and discovered that the above-described problems can be solved by, in a dry film which comprises a film and a photosensitive resin layer formed on the film, arranging the photosensitive resin layer having a gradient of an absorption coefficient (α) in a Z-axis direction, thereby completing the present invention.

That is, the dry film according to the present invention is a dry film comprising: a film; and a photosensitive resin layer formed on the film, wherein the absorption coefficient (α) of the photosensitive resin layer at a wavelength of 365 nm has an increase gradient or a decrease gradient from a surface of the photosensitive resin layer toward a surface of the film.

In the dry film according to the present invention, it is preferred that the gradient of the absorption coefficient (α) in the photosensitive resin layer is formed by a photopolymerization initiator or a coloring agent.

In the dry film according to the present invention, it is preferred that the gradient of the absorption coefficient (α) in the photosensitive resin layer is continuous or stepwise.

In the dry film according to the present invention, it is preferred that the photosensitive resin layer comprises two or more resin layers.

In the dry film according to the present invention, it is preferred that the photosensitive resin layer comprises a photosensitive resin composition containing a carboxyl group-containing photosensitive resin, a photopolymerization initiator or a coloring agent, a thermosetting component and an inorganic filler.

The laminated structure according to the present invention is a laminated structure comprising: a substrate; and a pattern layer which is formed on the substrate by exposing and developing a photosensitive resin layer of which an absorption coefficient (α) at a wavelength of 365 nm has an increase gradient from a surface of the resin layer toward a surface of the substrate, wherein the pattern layer includes a recessed part having a normal taper structure.

The printed writing board according to the present invention is a printed writing board comprising: a substrate; and a pattern layer which is formed on the substrate by exposing and developing a photosensitive resin layer of which an absorption coefficient (α) at a wavelength of 365 nm has an increase gradient from a surface of the resin layer toward a surface of the substrate, wherein the pattern layer is a solder resist which includes a recessed part having a normal taper structure.

Here, it is preferred that the photosensitive resin layer in the laminated structure and the printed writing board according to the present invention is formed by the photosensitive resin layer which constitutes any one of the above-described dry films.

The method of producing a laminated structure according to the present invention is a method of producing a laminated structure comprising: a first process in which a photosensitive resin layer, which is included in any one of the above-described dry films, is laminated on a substrate such that an absorption coefficient (α) at a wavelength of 365 nm has an increase gradient from a surface of the photosensitive resin layer toward a surface of the substrate; and a second process in which the photosensitive resin layer is exposed and developed to form a pattern layer which includes a recessed part having a normal taper structure.

### Effects of the Invention

By the present invention, it becomes possible to provide a dry film which can obtain a solder resist having an excellent resolution while maintaining various characteristics including PCT resistance, a laminated structure such as a printed writing board, and a method of producing the laminated structure.

### BRIEF DESCRIPTION OF THE DRAWINGS

FIG. 1 is a schematic view which shows a preferred embodiment of the dry film according to the present invention.

FIG. 2 is a schematic view which shows a cross-sectional structure of an opening part (a recessed part) for evaluating resolution about Examples. FIG. 2(A) is a view of a normal taper structure, (B) is a view of a reversed taper structure and (C) is a view of an undercut structure.

FIG. 3 is a picture of cross-section for evaluating resolution which shows a normal taper structure of Example 1.

FIG. 4 is a picture of cross-section for evaluating resolution which shows a reversed taper structure of Comparative Example 1.

FIG. 5 is a SEM picture of cross-section about Example 2.

FIG. 6 is a view which shows a result of analyzing an elemental P on a cross-section about Example 2 and shows a state of increasing the amount of elemental P toward a substrate.

FIG. 7 is a SEM picture of cross-section about Comparative Example 2.

FIG. 8 is a view which shows a result of analyzing an elemental P on a cross-section about Comparative Example 2 and shows a state of decreasing the amount of elemental P toward a substrate.

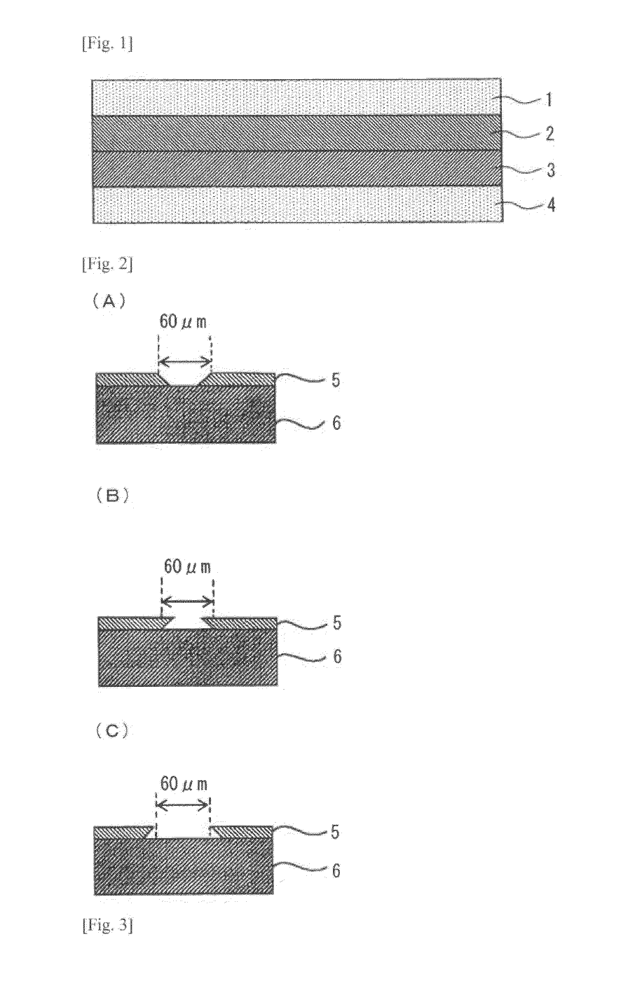

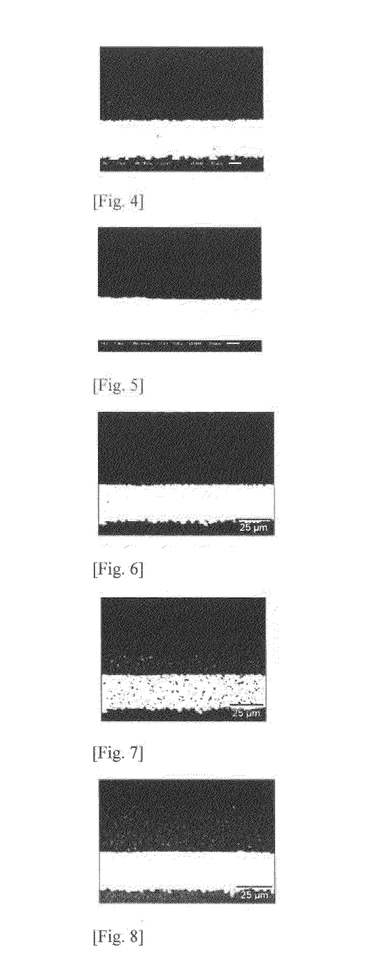

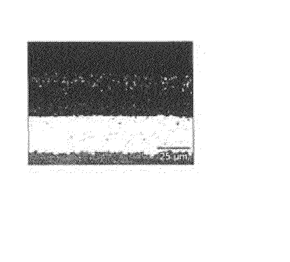

### MODE FOR CARRYING OUT THE INVENTION

### Dry Film

The dry film according to the present invention is a dry film comprising: a film; and a photosensitive resin layer formed on the film, wherein the absorption coefficient (α) of the photosensitive resin layer at a wavelength of 365 nm has an increase gradient or a decrease gradient from a surface of the photosensitive resin layer toward a surface of the film.

That is, in the dry film according to the present invention, the absorption coefficient (α) of the photosensitive resin layer at a wavelength of 365 nm has an increase gradient or a decrease gradient in a Z-axis direction. The Z-axis direction means a Z-axis direction when a plane of the film is regarded as an X-Y plane. In addition, the forming the gradient of the absorption coefficient means an absorption coefficient of the photosensitive resin layer at a certain point is higher or lower than that of the photosensitive resin layer at an another point of different positions in a Z-axis direction.

When the dry film according to the present invention is laminated on a substrate in a laminated structure, a photosensitive resin layer is laminated such that the absorption coefficient on the side which is in contact with the substrate comes into higher.

In this state, since the absorption coefficient of the photosensitive resin layer on the side which is in contact with the substrate is higher than that of the surface of the photosensitive resin layer on the opposite side of the substrate, a photo-curing is more promoted. Therefore, when a recessed part is formed by exposing and developing such photosensitive resin layer, the opening shape of the recessed part is a normal taper structure becoming gradually narrowed toward the substrate. In a solder process, the normal taper structure has an excellent adhesion of a solder. That is, by using the dry films according to the present invention, it is possible to form a solder resist (a pattern layer) having an excellent resolution.

As described in the above, the dry film of the present invention can be preferably used in the produce of the laminated structure according to the present invention and has, for example, two photosensitive resin layers 2 and 3 which are formed on a carrier film 4 shown in FIG. 1 such that the absorption coefficient (α) has a gradient in a Z-axis direction. In addition, it is preferred to have a cover film 1. Furthermore, although the same materials are used for the cover film and the carrier film in FIG. 1, different materials can be used. It is an example of the dry film shown in FIG. 1 that the absorption coefficient (α) of the photosensitive resin layer form a stepwise gradient. When the dry film is laminated on a substrate, the photosensitive resin layer may be laminated on the substrate such that the absorption coefficient (α) on the side which is in contact with the substrate comes into higher, so that in the the photosensitive resin layer of the dry film, the gradient of the absorption coefficient (α) on the side which is in contact with the carrier film can be formed to come into higher, or conversely into lower.

The absorption coefficient (α) can be obtained by determining an absorbance of a photosensitive resin layer in different film thicknesses at a wavelength of 365 nm, and then an inclination of a graph plotted with the film thickness and the absorbance.

The gradient of the absorption coefficient (α) in the photosensitive resin layer can be formed by controlling a concentration of a component having highly absorbance at a wavelength of 365 nm and, for example, it is preferred that the gradient is formed by the absorption coefficient of a photopolymerization initiator or a coloring agent.

The dry film according to the present invention can be produced by uniformly applying a photosensitive resin composition onto a carrier film using an appropriate means such as a blade coater, a lip coater, a comma coater, a film coater or the like; drying the resultant to form the photosensitive resin layer described in the above; and then, preferably, laminating a cover film thereon. In addition, in the dry film according to the present invention, layered structures in which the absorption coefficient (α) has “a stepwise gradient” and “a continuous gradient” can be separately formed by means of applying a photosensitive resin composition for forming the layered structures. For example, when a multi-layer structure is prepared by the steps of: applying a photosensitive resin composition onto a carrier film; drying the photosensitive resin composition; applying another photosensitive resin composition thereon; and again drying the resultant, since fluidity of the photosensitive resin composition through drying steps is lost, it is difficult for the compositions to diffuse between layers. As a result, a dry film having the layered structures in which the absorption coefficient (α) has the stepwise gradient can be obtained. Furthermore, in order to obtain the layered structures in which the absorption coefficient (α) has the continuous gradient, a multi-layer structure is prepared by the steps of: applying a photosensitive resin composition onto a carrier film; no drying or negligible drying to remain fluidity of the resultant; and applying another photosensitive resin composition thereon, thereby occurring diffusion of compositions at the interface. As a result, a dry film having the layered structures in which the absorption coefficient (α) has the continuous gradient can be obtained.

In case of preparing the dry film having a two-layer structure as shown in FIG. 1, for example, a photosensitive resin layer 2 (referred to as L1) having a higher absorption coefficient and a photosensitive resin layer 3 (referred to as L2) having a lower absorption coefficient may be formed on a carrier film in this order, or the photosensitive resin layer 3 and the photosensitive resin layer 2 may be formed on the carrier film in this order. When the dry film is laminated on a substrate, a film on the side of the photosensitive resin layer (L1) having a higher absorption coefficient may be removed to laminate the dry film on the substrate. The remained other film (the carrier film or the cover film) may be separated from the laminated dry film before or after the later-described exposing. These steps may also be applied to the case of the multi-layer structure having at least three layers.

In the dry film according to the present invention, the total thickness of the photosensitive resin layer is preferably not more than 100 μm, more preferably in the range of 5 to 50 μm. For example, in case of the dry film having two photosensitive resin layers as shown in FIG. 1, it is preferred that the first photosensitive resin layer (L1) having a higher absorption coefficient has a thickness of 1 to 50 μm and the second photosensitive resin layer (L2) having a lower absorption coefficient has a thickness of 1 to 50 μm. Here, the thickness ratio of the first photosensitive resin layer (L1) and the second photosensitive resin layer (L2) is preferably in the range of 1:9 to 9:1.

In the dry film according to the present invention, as a material of a carrier film and a cover film, any known material that may be used in a dry film can be employed.

As the carrier film, for example, a thermoplastic film such as a film made of polyester (e.g. polyethylene terephthalate), which has a thickness of 2 to 150 μm, may be employed.

As the cover film, a polyethylene film, a polypropylene film or the like may be employed, and the adhesive strength of the cover film with a photosensitive resin layer is preferably smaller than that of the carrier film.

### [Photosensitive Resin Composition]

In the dry film according to the present invention, it is preferred that the photosensitive resin layer comprises a photosensitive resin composition containing a carboxyl group-containing photosensitive resin, a photopolymerization initiator or a coloring agent, a thermosetting component and an inorganic filler.

In the present invention, a variety of conventionally known carboxyl group-containing resins having a carboxyl group in the molecule may be employed. In particular, from the standpoints of photocurability and resolution, a carboxyl group-containing photosensitive resin having an ethylenically unsaturated double bond in the molecule is preferred. It is preferred that the ethylenically unsaturated double bond be originated from acrylic acid, methacrylic acid or a derivative thereof. Here, in cases where a carboxyl group-containing non-photosensitive resin which does not have an ethylenically unsaturated double bond is used alone, in order to impart the composition with photocurability, it is required that the later-described compound having an ethylenically unsaturated group in the molecule, that is, a photo-polymerizable monomer be used in combination.

Specific examples of the carboxyl group-containing resin include the following compounds (that may each be either an oligomer or a polymer).

(1) A carboxyl group-containing photosensitive resin prepared by allowing a reaction product, which is obtained by a reaction between a compound having a plurality of phenolic hydroxyl groups in one molecule and an alkylene oxide such as ethylene oxide or propylene oxide, to react with an unsaturated group-containing monocarboxylic acid and then further allowing the thus obtained reaction product to react with a polybasic acid anhydride.

(2) A carboxyl group-containing photosensitive resin prepared by allowing the later-described polyfunctional (solid) epoxy resin, which has two or more functional groups, to react with (meth)acrylic acid and then adding a dibasic acid anhydride to a hydroxyl group existing in the side chain of the resultant.

(3) A carboxyl group-containing photosensitive resin prepared by allowing a polyfunctional epoxy resin, which is obtained by further epoxidizing a hydroxyl group of the later-described bifunctional (solid) epoxy resin with epichlorohydrin, to react with (meth)acrylic acid and then adding a dibasic acid anhydride to the resulting hydroxyl group.

(4) A carboxyl group-containing photosensitive resin prepared by allowing a reaction product, which is obtained by a reaction between a compound having a plurality of phenolic hydroxyl groups in one molecule and a cyclic carbonate compound such as ethylene carbonate or propylene carbonate, to react with an unsaturated group-containing monocarboxylic acid and then further allowing the thus obtained reaction product to react with a polybasic acid anhydride.

(5) A carboxyl group-containing photosensitive urethane resin obtained by a polyaddition reaction of a diisocyanate; a (meth)acrylate or partial acid anhydride-modified product of a bifunctional epoxy resin such as a bisphenol A-type epoxy resin, a hydrogenated bisphenol A-type epoxy resin, a bisphenol F-type epoxy resin, a bisphenol S-type epoxy resin, a bixylenol-type epoxy resin or a biphenol-type epoxy resin; a carboxyl group-containing dialcohol compound; and a diol compound.

(6) A carboxyl group-containing non-photosensitive resin obtained by copolymerization of an unsaturated carboxylic acid such as (meth)acrylic acid and an unsaturated group-containing compound such as styrene, α-methylstyrene, a lower alkyl (meth)acrylate or isobutylene.

(7) A carboxyl group-containing non-photosensitive urethane resin obtained by a polyaddition reaction of a diisocyanate (e.g. an aliphatic diisocyanate, a branched aliphatic diisocyanate, an alicyclic diisocyanate or an aromatic diisocyanate), a carboxyl group-containing dialcohol compound (e.g. dimethylol propionic acid or dimethylol butanoic acid) and a diol compound (e.g. a polycarbonate-based polyol, a polyether-based polyol, a polyester-based polyol, a polyolefin-based polyol, an acrylic polyol, a bisphenol A-type alkylene oxide adduct diol or a compound having a phenolic hydroxyl group and an alcoholic hydroxyl group).

(8) A carboxyl group-containing non-photosensitive polyester resin prepared by allowing the later-described bifunctional oxetane resin to react with a dicarboxylic acid such as adipic acid, phthalic acid or hexahydrophthalic acid and then adding a dibasic acid anhydride, such as phthalic anhydride, tetrahydrophthalic anhydride or hexahydrophthalic anhydride, to the resulting primary hydroxyl group.

(9) A carboxyl group-containing photosensitive urethane resin having a (meth)acrylated terminal, which is obtained by adding a compound having one hydroxyl group and at least one (meth)acryloyl group in the molecule, such as hydroxyalkyl (meth)acrylate, during the synthesis of the resin described in the above (5) or (7).

(10) A carboxyl group-containing photosensitive urethane resin having a (meth)acrylated terminal, which is obtained by adding a compound having one isocyanate group and at least one (meth)acryloyl group in the molecule, such as an equimolar reaction product of isophorone diisocyanate and pentaerythritol triacrylate, during the synthesis of the resin described in the above (5) or (7).

(11) A carboxyl group-containing photosensitive resin obtained by further adding a compound having one epoxy group and at least one (meth)acryloyl group in one molecule to any one of the resins described in the above (1) to (10).

Here, the term “(meth)acrylate” used herein is a general term for acrylates, methacrylates and mixtures thereof and this is hereinafter applicable to all similar expressions.

Since such carboxyl group-containing resins described in the above have a number of carboxyl groups in the side chain of the backbone polymer, they can be developed with a dilute aqueous alkaline solution.

Further, the above-described carboxyl group-containing resin has an acid value in the range of appropriately 40 to 200 mg KOH/g, more preferably 45 to 120 mg KOH/g. When the acid value of the carboxyl group-containing resin is less than 40 mg KOH/g, development with an alkali may become difficult. Meanwhile, when the acid value is higher than 200 mg KOH/g, since the developing solution further dissolves the exposed part, the resulting lines may become excessively thin and in some cases, the exposed and non-exposed parts may be indistinctively dissolved and detached by the developing solution, making it difficult to draw a normal resist pattern; therefore, such an acid value is not preferred.

Further, the weight-average molecular weight of the above-described carboxyl group-containing resin varies depending on the resin skeleton; however, in general, it is preferably in the range of 2,000 to 150,000, more preferably in the range of 5,000 to 100,000. When the weight-average molecular weight is less than 2,000, the tack-free performance may be impaired and the moisture resistance of the resulting coating film after exposure may be deteriorated to cause a reduction in the film during development, which may greatly deteriorate the resolution. Meanwhile, when the weight-average molecular weight exceeds 150,000, the developing property may be markedly deteriorated and the storage stability may be impaired.

The content of such carboxyl group-containing resin is in the range of appropriately 20 to 60% by mass, preferably 30 to 50% by mass, based on the total amount of the composition. When the content of the carboxyl group-containing resin is less than the above-described range, for example, the strength of the resulting coating film may be reduced, which is not preferred. Meanwhile, when the content is higher than the above-described range, the viscosity of the composition may be increased and the coating properties and the like may be deteriorated, which are not preferred.

The carboxyl group-containing resin is not restricted to those enumerated in the above, and these carboxyl group-containing resins described in the above may be used individually, or two or more thereof may be used in combination. In particular, among the above-described carboxyl group-containing resins, those having an aromatic ring are preferred since they have a high refractive index and an excellent resolution, and those having a novolac structure are more preferred since they not only have a high resolution but also are excellent in PCT and cracking resistance. Thereamong, the carboxyl group-containing photosensitive resins (1) and (2) are preferred since they can yield a solder resist having satisfactory properties such as PCT resistance, as well as an excellent resolution.

The photosensitive resin composition for forming the photosensitive resin layer includes a photopolymerization initiator. As the photopolymerization initiator, at least one photopolymerization initiator selected from the group consisting of oxime ester-based photopolymerization initiators having an oxime ester group, alkylphenone-based photopolymerization initiators, α-aminoacetophenone-based photopolymerization initiators, acylphosphine oxide-based photopolymerization initiators and titanocene-based photopolymerization initiators can be suitably used.

Particularly, the above-described oxime ester-based photopolymerization initiators are preferred since they can inhibit generation of outgas only in a small amount and exhibits an effect of imparting PCT resistance and cracking resistance.

Examples of commercially available oxime ester-based photopolymerization initiator include CGI-325, IRGACURE OXE01 and IRGACURE OXE02, which are manufactured by BASF Japan Ltd.; and N-1919 and NCI-831, which are manufactured by ADEKA CORPORATION. Further, a photopolymerization initiator having two oxime ester groups in the molecule can also be suitably used, and specific examples thereof include those oxime ester compounds having a carbazole structure which are represented by the following formula:

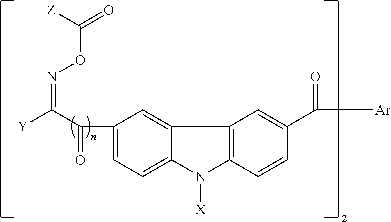

(wherein, X represents a hydrogen atom, an alkyl group having 1 to 17 carbon atoms, an alkoxy group having 1 to 8 carbon atoms, a phenyl group, a phenyl group (which is substituted with an alkyl group having 1 to 17 carbon atoms, an alkoxy group having 1 to 8 carbon atoms, an amino group, or an alkylamino or dialkylamino group containing an alkyl group having 1 to 8 carbon atoms), a naphthyl group (which is substituted with an alkyl group having 1 to 17 carbon atoms, an alkoxy group having 1 to 8 carbon atoms, an amino group, or an alkylamino or dialkylamino group containing an alkyl group having 1 to 8 carbon atoms); Y and Z each independently represent a hydrogen atom, an alkyl group having 1 to 17 carbon atoms, an alkoxy group having 1 to 8 carbon atoms, a halogen group, a phenyl group, a phenyl group (which is substituted with an alkyl group having 1 to 17 carbon atoms, an alkoxy group having 1 to 8 carbon atoms, an amino group, or an alkylamino or dialkylamino group containing an alkyl group having 1 to 8 carbon atoms), a naphthyl group (which is substituted with an alkyl group having 1 to 17 carbon atoms, an alkoxy group having 1 to 8 carbon atoms, an amino group, or an alkylamino or dialkylamino group containing an alkyl group having 1 to 8 carbon atoms), an anthryl group, a pyridyl group, a benzofuryl group or a benzothienyl group; Ar represents a bond, an alkylene having 1 to 10 carbon atoms, a vinylene, a phenylene, a biphenylene, a pyridylene, a naphthylene, a thiophene, an anthrylene, a thienylene, a furylene, 2,5-pyrrole-diyl, 4,4′-stilbene-diyl or 4,2′-styrene-diyl; and n is an integer of 0 or 1).

Particularly, in the above-described formula, it is preferred that X and Y be each a methyl group or an ethyl group; Z be methyl or phenyl; n be 0; and Ar be a bond, a phenylene, a naphthylene, a thiophene or a thienylene.

Further, examples of preferred carbazole oxime ester compound include those compounds that are represented by the following formula:

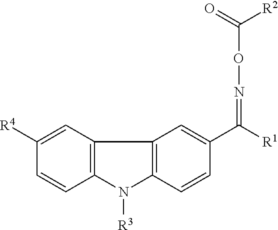

(wherein, R¹ represents an alkyl group having 1 to 4 carbon atoms or a phenyl group which is optionally substituted with a nitro group, a halogen atom or an alkyl group having 1 to 4 carbon atoms;

R² represents an alkyl group having 1 to 4 carbon atoms, an alkoxy group having 1 to 4 carbon atoms or a phenyl group which is optionally substituted with an alkyl or alkoxy group having 1 to 4 carbon atoms;

R³ is optionally linked via an oxygen atom or a sulfur atom and represents an alkyl group having 1 to 20 carbon atoms which is optionally substituted with a phenyl group or a benzyl group which is optionally substituted with an alkoxy group having 1 to 4 carbon atoms;

R⁴ represents a nitro group or an acyl group represented by X—C(═O)—; and

X represents an aryl group which is optionally substituted with an alkyl group having 1 to 4 carbon atoms, a thienyl group, a morpholino group, a thiophenyl group or a structure represented by the following formula).

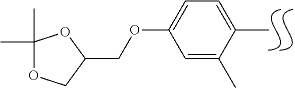

In addition to the above, examples of preferred carbazole oxime ester compound include those described in Japanese Unexamined Patent Application Publication Nos. 2004-359639, 2005-097141, 2005-220097, 2006-160634, 2008-094770 and 2011-80036 and Japanese Translated PCT Patent Application Laid-open Nos. 2008-509967 and 2009-040762.

The content of such oxime ester-based photopolymerization initiator is preferably 0.01 to 5 parts by mass, more preferably 0.25 to 3 parts by mass, with respect to 100 parts by mass of the carboxyl group-containing resin.

By controlling the content in the range of 0.01 to 5 parts by mass, a solder resist which not only has an excellent photocurability and resolution, but also has an improved adhesive property and PCT resistance and exhibits excellent chemical resistance such as resistance to electroless gold plating, can be obtained.

In contrast, when the content is less than 0.01 parts by mass, not only the photocurability on copper becomes insufficient and the coating film of the resulting solder resist is detached, but also the properties of the coating film such as chemical resistance are deteriorated. Meanwhile, when the content is higher than 5 parts by mass, since light absorption on the surface of the coating film of the resulting solder resist becomes intense, the curability in a deep portion tends to be impaired.

Examples of commercially available alkylphenone-based photopolymerization initiator include α-hydroxyalkylphenone-type photopolymerization initiators such as IRGACURE 184, DAROCUR 1173, IRGACURE 2959 and IRGACURE 127 (2-hydroxy-1-{4-[4-(2-hydroxy-2-methyl-propionyl)-benzyl]-phenyl}-2-methyl-propan-1-one), all of which are manufactured by BASF Japan Ltd.

Specific examples of the α-aminoacetophenone-based photopolymerization initiator include 2-methyl-1-[4-(methylthio)phenyl]-2-morpholinopropanone-1,2-benzyl-2-dimethylamino-1-(4-morpholinophenyl)-butane-1-one, 2-(dimethylamino)-2-[(4-methylphenyl)methyl]-1-[4-(4-morpholinyl)phenyl]-1-butanone and N,N-dimethylaminoacetophenone. Examples of commercially available α-aminoacetophenone-based photopolymerization initiator include IRGACURE 907, IRGACURE 369 and IRGACURE 379, all of which are manufactured by BASF Japan Ltd.

Specific examples of the acylphosphine oxide-based photopolymerization initiator include 2,4,6-trimethylbenzoyl diphenylphosphine oxide, bis(2,4,6-trimethylbenzoyl)-phenylphosphine oxide and bis(2,6-dimethoxybenzoyl)-2,4,4-trimethyl-pentylphosphine oxide. Examples of commercially available acylphosphine oxide-based photopolymerization initiator include LUCIRIN TPO manufactured by BASF SE and IRGACURE 819 manufactured by BASF Japan Ltd.

The content of such α-aminoacetophenone-based photopolymerization initiator and acylphosphine oxide-based photopolymerization initiator is preferably 0.1 to 25 parts by mass, more preferably 1 to 20 parts by mass, with respect to 100 parts by mass of the carboxyl group-containing resin.

By controlling the content in the range of 0.1 to 25 parts by mass, a solder resist which not only has an excellent photocurability and resolution, but also has an improved adhesive property and PCT resistance and exhibits excellent chemical resistance such as resistance to electroless gold plating, can be obtained.

In contrast, when the content is less than 0.1 parts by mass, not only the photocurability on copper becomes insufficient in the same manner and the resulting solder resist is detached, but also the properties of the coating film such as chemical resistance are deteriorated. Meanwhile, when the content is higher than 25 parts by mass, an outgas-reducing effect cannot attained and the light absorption on the surface of the resulting solder resist becomes intense, so that the curability in a deep portion of the solder resist tends to be impaired.

Further, as the photopolymerization initiator, IRGACURE 389 manufactured by BASF Japan Ltd. can also be suitably used. The content of IRGACURE 389 is suitably 0.1 to 20 parts by mass, more suitably 1 to 15 parts by mass, with respect to 100 parts by mass of the carboxyl group-containing resin.

Further, a titanocene-based photopolymerization initiator such as IRGACURE 784 (bis(η⁵-2,4-cylcopentadien-1-yl)-bis(2,6-difluoro-3-(1H-pyrrol-1-yl)-phenyl) titanium) can also be suitably used. The content of such titanocene-based photopolymerization initiator is suitably 0.01 to 5 parts by mass, more suitably 0.01 to 3 parts by mass, with respect to 100 parts by mass of the carboxyl group-containing resin.

By controlling the content of these photopolymerization initiators at a suitable level, a solder resist which not only has an excellent photocurability and resolution, but also has an improved adhesive property and PCT resistance and exhibits excellent chemical resistance such as resistance to electroless gold plating, can be obtained.

In contrast, when the content is less than a suitable level, not only the photocurability on copper becomes insufficient and the resulting solder resist is detached, but also the properties of the coating film such as chemical resistance are deteriorated. Meanwhile, when the content is higher than a suitable level, since light absorption on the surface of the resulting solder resist becomes intense, the curability in a deep portion tends to be impaired.

In the above-described photopolymerization initiator, a compound containing a nitrogen, a phosphorus, a sulfur or a titanium atom is particularly preferred.

The above-described photosensitive resin composition may also contain a photoinitiator aid and/or a sensitizer in addition to a photopolymerization initiator. Examples of the photopolymerization initiator, the photoinitiator aid and the sensitizer that can be suitably used in the photosensitive resin composition include benzoin compounds, acetophenone compounds, anthraquinone compounds, thioxanthone compounds, ketal compounds, benzophenone compounds, tertiary amine compounds and xanthone compounds.

Specific examples of the benzoin compounds include benzoin, benzoin methyl ether, benzoin ethyl ether and benzoin isopropyl ether.

Specific examples of the acetophenone compounds include acetophenone, 2,2-dimethoxy-2-phenyl acetophenone, 2,2-diethoxy-2-phenyl acetophenone and 1,1-dichloroacetophenone.

Specific examples of the anthraquinone compounds include 2-methylanthraquinone, 2-ethylanthraquinone, 2-t-butylanthraquinone and 1-chloroanthraquinone.

Specific examples of the thioxanthone compounds include 2,4-dimethylthioxanthone, 2,4-diethylthioxanthone, 2-chlorothioxanthone and 2,4-diisopropylthioxanthone.

Specific examples of the ketal compounds include acetophenone dimethyl ketal and benzyldimethyl ketal.

Specific examples of the benzophenone compounds include benzophenone, 4-benzoyldiphenylsulfide, 4-benzoyl-4′-methyldiphenylsulfide, 4-benzoyl-4′-ethyldiphenylsulfide and 4-benzoyl-4′-propyldiphenylsulfide.

Specific examples of the tertiary amine compounds include ethanolamine compounds and compounds having a dialkylaminobenzene structure, and examples of commercially available products thereof include dialkylaminobenzophenones such as 4,4′-dimethylaminobenzophenone (NISSO CURE MABP manufactured by Nippon Soda Co., Ltd.) and 4,4′-diethylaminobenzophenone (EAB manufactured by Hodogaya Chemical Co., Ltd.); dialkylamino group-containing coumarin compounds such as 7-(diethylamino)-4-methyl-2H-1-benzopyran-2-one (7-(diethylamino)-4-methylcoumarin); ethyl-4-dimethylaminobenzoate (KAYACURE EPA manufactured by Nippon Kayaku Co., Ltd.); ethyl-2-dimethylaminobenzoate (QUANTACURE DMB manufactured by International BioSynthetics Ltd.); (n-butoxy)ethyl-4-dimethylaminobenzoate (QUANTACURE BEA manufactured by International BioSynthetics Ltd.); isoamylethyl-p-dimethylaminobenzoate (KAYACURE DMBI manufactured by Nippon Kayaku Co., Ltd.); 2-ethylhexyl-4-dimethylaminobenzoate (ESOLOL 507 manufactured by Van Dyk GmbH); and 4,4′-diethylaminobenzophenone (EAB manufactured by Hodogaya Chemical Co., Ltd.).

Among the above-described compounds, thioxanthone compounds and tertiary amine compounds are preferred. In particular, from the standpoint of the curability of the resulting coating film in a deep portion, it is preferred that a thioxanthone compound such as 2,4-dimethylthioxanthone, 2,4-diethylthioxanthone, 2-chlorothioxanthone or 2,4-diisopropylthioxanthone be incorporated.

The content of such thioxanthone compound is preferably not higher than 20 parts by mass with respect to 100 parts by mass of the above-described carboxyl group-containing resin. When the content of the thioxanthone compound is higher than 20 parts by mass, the thick film curability is deteriorated, leading to an increase in the production cost. The content of the thioxanthone compound is more preferably not higher than 10 parts by mass.

Further, as the tertiary amine compound, those compounds having a dialkylaminobenzene structure are preferred. Thereamong, dialkylaminobenzophenone compounds; and dialkylamino group-containing coumarin compounds that have a maximum absorption wavelength in the range of 350 to 450 nm and ketocumarines are particularly preferred.

As the dialkylaminobenzophenone compound, 4,4′-diethylaminobenzophenone is preferred because of its low toxicity. Since the dialkylamino group-containing coumarin compound has a maximum absorption wavelength in the ultraviolet region of 350 to 410 nm, it causes little coloration, so that not only a colorless and transparent photosensitive composition can be provided, but also a colored solder resist which reflects the color of a coloring pigment itself can be provided by using a coloring pigment. In particular, 7-(diethylamino)-4-methyl-2H-1-benzopyran-2-one is preferred since it exhibits an excellent sensitization effect against a laser beam having a wavelength of 400 to 410 nm.

The content of such tertiary amine compound is preferably 0.1 to 20 parts by mass with respect to 100 parts by mass of the above-described carboxyl group-containing resin. When the content of the tertiary amine compound is less than 0.1 parts by mass, sufficient sensitization effect is not likely to be attained. Meanwhile, when the content is higher than 20 parts by mass, the light absorption by the tertiary amine compound on the surface of a dried solder resist is increased, so that the curability of the solder resist in a deep portion tends to be impaired. The content of the tertiary amine compound is more preferably 0.1 to 10 parts by mass.

These photopolymerization initiators, photoinitiator aids and sensitizers may be used individually, or two or more thereof may be used in the form of a mixture.

It is preferred that the combined amount of photopolymerization initiators, photoinitiator aids and sensitizers be not more than 35 parts by mass with respect to 100 parts by mass of the above-described carboxyl group-containing resin. When the amount exceeds 35 parts by mass, the light absorption by these components tends to deteriorate the curability of a deep portion.

Here, since these photopolymerization initiators, photoinitiator aids and sensitizers absorb a particular wavelength, the sensitivity may be lower and these may be performed as ultraviolet absorbing agents in some cases.

Furthermore, the photosensitive resin composition used in the present invention may also contain a coloring agent. As the coloring agent, a commonly used and known coloring agent of red, blue, green, yellow or the like may be employed, and it may be any of a pigment, a stain or a dye. Specific examples of the coloring agent include those assigned with the following Color Index numbers (C.I.; issued by The Society of Dyers and Colourists). Here, from the standpoints of reducing the environmental stress and the effects on human body, it is preferred that the coloring agent contain no halogen.

### Red Coloring Agent:

Examples of red coloring agent include monoazo-type, disazo-type, azo lake-type, benzimidazolone-type, perylene-type, diketopyrrolopyrrole-type, condensed azo-type, anthraquinone-type and quinacridone-type red coloring agents, and specific examples thereof include the followings.

Monoazo-type: Pigment Red 1, 2, 3, 4, 5, 6, 8, 9, 12, 14, 15, 16, 17, 21, 22, 23, 31, 32, 112, 114, 146, 147, 151, 170, 184, 187, 188, 193, 210, 245, 253, 258, 266, 267, 268 and 269

Disazo-type: Pigment Red 37, 38 and 41 Monoazo lake-type: Pigment Red 48:1, 48:2, 48:3, 48:4, 49:1, 49:2, 50:1, 52:1, 52:2, 53:1, 53:2, 57:1, 58:4, 63:1, 63:2, 64:1 and 68

Benzimidazolone-type: Pigment Red 171, Pigment Red 175, Pigment Red 176, Pigment Red 185 and Pigment Red 208

Perylene-type: Solvent Red 135, Solvent Red 179, Pigment Red 123, Pigment Red 149, Pigment Red 166, Pigment Red 178, Pigment Red 179, Pigment Red 190, Pigment Red 194 and Pigment Red 224

Diketopyrrolopyrrole-type: Pigment Red 254, Pigment Red 255, Pigment Red 264, Pigment Red 270 and Pigment Red 272

Condensed azo-type: Pigment Red 220, Pigment Red 144, Pigment Red 166, Pigment Red 214, Pigment Red 220, Pigment Red 221 and Pigment Red 242

Anthraquinone-type: Pigment Red 168, Pigment Red 177, Pigment Red 216, Solvent Red 149, Solvent Red 150, Solvent Red 52 and Solvent Red 207

Quinacridone-type: Pigment Red 122, Pigment Red 202, Pigment Red 206, Pigment Red 207 and Pigment Red 209 Blue Coloring Agent:

Examples of blue coloring agent include phthalocyanine-type and anthraquinone-type blue coloring agents and examples of pigment-type blue coloring agent include those compounds that are classified into pigment. Specific examples thereof include Pigment Blue 15, Pigment Blue 15:1, Pigment Blue 15:2, Pigment Blue 15:3, Pigment Blue 15:4, Pigment Blue 15:6, Pigment Blue 16 and Pigment Blue 60.

As a stain-type blue coloring agent, for example, Solvent Blue 35, Solvent Blue 63, Solvent Blue 68, Solvent Blue 70, Solvent Blue 83, Solvent Blue 87, Solvent Blue 94, Solvent Blue 97, Solvent Blue 122, Solvent Blue 136, Solvent Blue 67 and Solvent Blue 70 can be used. In addition to the above-described ones, a metal-substituted or unsubstituted phthalocyanine compound can be used as well.

### Green Coloring Agent:

Similarly, examples of green coloring agent include phthalocyanine-type, anthraquinone-type and perylene-type green coloring agents and specifically, for example, Pigment Green 7, Pigment Green 36, Solvent Green 3, Solvent Green 5, Solvent Green 20 and Solvent Green 28 can be used. In addition to the above-described ones, a metal-substituted or unsubstituted phthalocyanine compound can be used as well.

### Yellow Coloring Agent:

Examples of yellow coloring agent include monoazo-type, disazo-type, condensed azo-type, benzimidazolone-type, isoindolinone-type and anthraquinone-type yellow coloring agents and specific examples thereof include the followings.

Anthraquinone-type: Solvent Yellow 163, Pigment Yellow 24, Pigment Yellow 108, Pigment Yellow 193, Pigment Yellow 147, Pigment Yellow 199 and Pigment Yellow 202.

Isoindolinone-type: Pigment Yellow 110, Pigment Yellow 109, Pigment Yellow 139, Pigment Yellow 179 and Pigment Yellow 185.

Condensed azo-type: Pigment Yellow 93, Pigment Yellow 94, Pigment Yellow 95, Pigment Yellow 128, Pigment Yellow 155, Pigment Yellow 166 and Pigment Yellow 180.

Benzimidazolone-type: Pigment Yellow 120, Pigment Yellow 151, Pigment Yellow 154, Pigment Yellow 156, Pigment Yellow 175 and Pigment Yellow 181.

Monoazo-type: Pigment Yellow 1, 2, 3, 4, 5, 6, 9, 10, 12, 61, 62, 62:1, 65, 73, 74, 75, 97, 100, 104, 105, 111, 116, 167, 168, 169, 182, 183.

Disazo-type: Pigment Yellow 12, 13, 14, 16, 17, 55, 63, 81, 83, 87, 126, 127, 152, 170, 172, 174, 176, 188, and 198.

In addition to the above, in order to adjust the color tone, for example, a violet, orange, brown and/or black coloring agent(s) may also be added.

Specific examples of such coloring agent include Pigment Violet 19, 23, 29, 32, 36, 38 and 42, Solvent Violet 13 and 36, C.I. Pigment Orange 1, C.I. Pigment Orange 5, C.I. Pigment Orange 13, C.I. Pigment Orange 14, C.I. Pigment Orange 16, C.I. Pigment Orange 17, C.I. Pigment Orange 24, C.I. Pigment Orange 34, C.I. Pigment Orange 36, C.I. Pigment Orange 38, C.I. Pigment Orange 40, C.I. Pigment Orange 43, C.I. Pigment Orange 46, C.I. Pigment Orange 49, C.I. Pigment Orange 51, C.I. Pigment Orange 61, C.I. Pigment Orange 63, C.I. Pigment Orange 64, C.I. Pigment Orange 71, C.I. Pigment Orange 73, C.I. Pigment Brown 23, C.I. Pigment Brown 25, C.I. Pigment Black 1 and C.I. Pigment Black 7.

The above-described coloring agents may be blended as appropriate and the content thereof is preferably not higher than 10 parts by mass, more preferably 0.1 to 5 parts by mass, with respect to 100 parts by mass of the above-described carboxyl group-containing resin or a thermosetting component.

A thermosetting component may be added to the photosensitive resin composition used in the present invention. By adding the thermosetting component, improving the heat resistance is confirmed. Examples of such thermosetting component used in the present invention include amino resins such as melamine resins, benzoguanamine resins, melamine derivatives and benzoguanamine derivatives; blocked isocyanate compounds; cyclocarbonate compounds; polyfunctional epoxy compounds; polyfunctional oxetane compounds; and known thermosetting resins such as episulfide resins, bismaleimides and carbodiimide resins. Thereamong, a thermosetting component having a cyclic ether group and/or a cyclic thioether group (hereinafter, simply referred to as “cyclic (thio)ether group”) in a plural number in the molecule is particularly preferred.

The above-described thermosetting component having a plurality of cyclic (thio)ether groups in the molecule is a compound having any one of or two of 3-, 4- and 5-membered cyclic (thio)ether groups in the molecule. Examples of such compound include compounds having a plurality of epoxy groups in the molecule, that is, polyfunctional epoxy compounds; compounds having a plurality of oxetanyl groups in the molecule, that is, polyfunctional oxetane compounds; and compounds having a plurality of thioether groups in the molecule, that is, episulfide resins.

Examples of the above-described polyfunctional epoxy compounds include, but not limited to, epoxidized vegetable oils such as ADK CIZER O-130P, ADK CIZER O-180A, ADK CIZER D-32 and ADK CIZER D-55, which are manufactured by ADEKA CORPORATION; bisphenol A-type epoxy resins such as jER828, jER834, jER1001 and jER1004, which are manufactured by Mitsubishi Chemical Corporation, EHPE3150 manufactured by Daicel Corporation, EPICLON 840, EPICLON 850, EPICLON 1050 and EPICLON 2055, which are manufactured by DIC Corporation, EPOTOHTO YD-011, YD-013, YD-127 and YD-128, which are manufactured by NIPPON STEEL & SUMIKIN CHEMICAL CO., LTD., D.E.R.317, D.E.R.331, D.E.R.661 and D.E.R.664, which are manufactured by The Dow Chemical Company, Araldite 6071, Araldite 6084, Araldite GY250 and Araldite GY260, which are manufactured by BASF Japan Ltd., SUMI-EPDXY ESA-011, ESA-014, ELA-115 and ELA-128, which are manufactured by Sumitomo Chemical Co., Ltd., and A.E.R.330, A.E.R.331, A.E.R.661 and A.E.R.664, which are manufactured by Asahi Kasei Corporation. (all of the above are trade names); hydroquinone-type epoxy resin YDC-1312, bisphenol-type epoxy resin YSLV-80XY and thioether-type epoxy resin YSLV-120TE (all of which are manufactured by NIPPON STEEL & SUMIKIN CHEMICAL CO., LTD.); brominated epoxy resins such as jERYL903 manufactured by Mitsubishi Chemical Corporation, EPICLON 152 and EPICLON 165, which are manufactured by DIC Corporation, EPOTOHTO YDB-400 and YDB-500, which are manufactured by NIPPON STEEL & SUMIKIN CHEMICAL CO., LTD., D.E.R.542 manufactured by The Dow Chemical Company, Araldite 8011 manufactured by BASF Japan Ltd., SUMI-EPDXY ESB-400 and ESB-700, which are manufactured by Sumitomo Chemical Co., Ltd., and A.E.R.711 and A.E.R.714, which are manufactured by Asahi Kasei Corporation. (all of the above are trade names); novolac-type epoxy resins such as jER152 and jER154, which are manufactured by Mitsubishi Chemical Corporation, D.E.N.431 and D.E.N.438, which are manufactured by The Dow Chemical Company, EPICLON N-730, EPICLON N-770 and EPICLON N-865, which are manufactured by DIC Corporation, EPOTOHTO YDCN-701 and YDCN-704, which are manufactured by NIPPON STEEL & SUMIKIN CHEMICAL CO., LTD., Araldite ECN1235, Araldite ECN1273, Araldite ECN1299 and Araldite XPY307, which are manufactured by BASF Japan Ltd., EPPN-201, EOCN-1025, EOCN-1020, EOCN-104S and RE-306, which are manufactured by Nippon Kayaku Co., Ltd., SUMI-EPDXY ESCN-195X and ESCN-220, which are manufactured by Sumitomo Chemical Co., Ltd., and A.E.R.ECN-235 and ECN-299, which are manufactured by Asahi Kasei Corporation., (all of the above are trade names); biphenol novolac-type epoxy resins such as NC-3000 and NC-3100, which are manufactured by Nippon Kayaku Co., Ltd.; bisphenol F-type epoxy resins such as EPICLON 830 manufactured by DIC Corporation, jER807 manufactured by Mitsubishi Chemical Corporation, and EPOTOHTO YDF-170, YDF-175 and YDF-2004 which are manufactured by NIPPON STEEL & SUMIKIN CHEMICAL CO., LTD. and Araldite XPY306 manufactured by BASF Japan Ltd. (all of the above are trade names); hydrogenated bisphenol A-type epoxy resins such as EPOTOHTO ST-2004, ST-2007 and ST-3000 (trade names) which are manufactured by NIPPON STEEL & SUMIKIN CHEMICAL CO., LTD.; glycidyl amine-type epoxy resins such as jER604 manufactured by Mitsubishi Chemical Corporation, EPOTOHTO YH-434 manufactured by NIPPON STEEL & SUMIKIN CHEMICAL CO., LTD., Araldite MY720 manufactured by BASF Japan Ltd. and SUMI-EPDXY ELM-120 manufactured by Sumitomo Chemical Co., Ltd. (all of the above are trade names); hydantoin-type epoxy resins such as Araldite CY-350 manufactured by BASF Japan Ltd. (the trade name); alicyclic epoxy resins such as CELLOXIDE 2021 manufactured by Daicel Corporation, and Araldite CY 175 and CY179, which are manufactured by BASF Japan Ltd. (all of the above are trade names); trihydroxyphenyl methane-type epoxy resins such as YL-933 manufactured by Mitsubishi Chemical Corporation and T.E.N., EPPN-501 and EPPN-502, which are manufactured by The Dow Chemical Company (all of the above are trade names); bixylenol-type or biphenol-type epoxy resins and mixtures thereof, such as YL-6056, YX-4000 and YL-6121 (all of which are trade names) manufactured by Mitsubishi Chemical Corporation; bisphenol S-type epoxy resins such as EBPS-200 manufactured by Nippon Kayaku Co., Ltd., EPX-30 manufactured by ADEKA CORPORATION and EXA-1514 (trade name) manufactured by DIC Corporation; bisphenol A novolac-type epoxy resins such as jER157S (trade name) manufactured by Mitsubishi Chemical Corporation; tetraphenylolethane-type epoxy resins such as jERYL-931 manufactured by Mitsubishi Chemical Corporation and Araldite 163 manufactured by BASF Japan Ltd. (all of the above are trade names); heterocyclic epoxy resins such as Araldite PT810 manufactured by BASF Japan Ltd. and TEPIC manufactured by Nissan Chemical Industries, Ltd. (all of the above are trade names); diglycidyl phthalate resins such as BLEMMER DGT manufactured by NOF Corporation; tetraglycidyl xylenoylethane resins such as ZX-1063 manufactured by NIPPON STEEL & SUMIKIN CHEMICAL CO., LTD.; naphthalene group-containing epoxy resins such as ESN-190 and ESN-360, which are manufactured by NIPPON STEEL & SUMIKIN CHEMICAL CO., LTD., and HP-4032, EXA-4750 and EXA-4700, which are manufactured by DIC Corporation; epoxy resins having a dicyclopentadiene skeleton, such as HP-7200 and HP-7200H manufactured by DIC Corporation; glycidyl methacrylate copolymer-based epoxy resins such as CP-50S and CP-50M manufactured by NOF Corporation; cyclohexylmaleimide-glycidyl methacrylate copolymer epoxy resins; epoxy-modified polybutadiene rubber derivatives (for example, PB-3600 manufactured by Daicel Corporation); and CTBN-modified epoxy resins (for example, YR-102 and YR-450 manufactured by NIPPON STEEL & SUMIKIN CHEMICAL CO., LTD.). These epoxy resins may be used individually, or two or more thereof may be used in combination. Thereamong, novolac-type epoxy resins, bixylenol-type epoxy resins, biphenol-type epoxy resins, biphenol novolac-type epoxy resins, naphthalene-type epoxy resins or mixtures thereof is particularly preferred.

Examples of the polyfunctional oxetane compounds include polyfunctional oxetanes such as bis[(3-methyl-3-oxcetanylmethoxy)methyl]ether, bis[(3-ethyl-3-oxcetanylmethoxy)methyl]ether, 1,4-bis[(3-methyl-3-oxcetanylmethoxy)methyl]benzene, 1,4-bis[(3-ethyl-3-oxcetanylmethoxy)methyl]benzene, (3-methyl-3-oxcetanyl)methyl acrylate, (3-ethyl-3-oxcetanyl)methyl acrylate, (3-methyl-3-oxcetanyl)methyl methacrylate, (3-ethyl-3-oxcetanyl)methyl methacrylate, and oligomers or copolymers thereof; and etherification products of an oxetane alcohol and a resin having a hydroxyl group such as a novolac resin, a poly(p-hydroxystyrene), a cardo-type bisphenol, a calixarene, a calix resorcin arene or a silsesquioxane. In addition, examples of the polyfunctional oxetane compounds also include copolymers of an unsaturated monomer having an oxetane ring and an alkyl(meth)acrylate.

Examples of the compounds having a plurality of cyclic thioether groups in the molecule include bisphenol A-type episulfide resin YL7000 manufactured by Mitsubishi Chemical Corporation. Further, for example, an episulfide resin prepared by the same synthesis method, in which an oxygen atom of an epoxy group of a novolac-type epoxy resin is substituted with a sulfur atom, can also be used.

The content of such thermosetting component having a plurality of cyclic (thio)ether groups in the molecule is preferably 0.6 to 2.5 equivalents with respect to 1 equivalent of carboxyl group in the above-described carboxyl group-containing resin. When the content is less than 0.6 equivalent, the carboxyl group remains in the resulting solder resist, causing deterioration in the heat resistance, alkali resistance, electrical insulation properties and the like. Meanwhile, when the content is higher than 2.5 equivalents, cyclic (thio)ether groups having a low molecular weight remain in the resulting dry coating film, causing deterioration in the coating film strength and the like. The content of the thermosetting component having a plurality of cyclic (thio)ether groups in the molecule is more preferably 0.8 to 2.0 equivalents.

Further, examples of other thermosetting component include amino resins such as melamine derivatives and benzoguanamine derivatives, such as methylol melamine compounds, methylol benzoguanamine compounds, methylol glycoluril compounds and methylol urea compounds. Moreover, alkoxymethylated melamine compounds, alkoxymethylated benzoguanamine compounds, alkoxymethylated glycoluril compounds and alkoxymethylated urea compounds are obtained by converting the methylol group of the respective methylol melamine compounds, methylol benzoguanamine compounds, methylol glycoluril compounds and methylol urea compounds into an alkoxymethyl group. The type of this alkoxymethyl group is not particularly restricted and examples thereof include methoxymethyl group, ethoxymethyl group, propoxymethyl group and butoxymethyl group. In particular, a melamine derivative having a formalin concentration of not higher than 0.2%, which is not harmful to human body and environment, is preferred.

Examples of commercially available products of the above-described thermosetting components include CYMEL 300, 301, 303, 370, 325, 327, 701, 266, 267, 238, 1141, 272, 202, 1156, 1158, 1123, 1170, 1174, UFR65 and 300 (all of which are manufactured by MT AquaPolymer, Inc.); and NIKALAC Mx-750, Mx-032, Mx-270, Mx-280, Mx-290, Mx-706, Mx-708, Mx-40, Mx-31, Ms-11, Mw-30, Mw-30HM, Mw-390, Mw-100LM and Mw-750LM (all of which are manufactured by SANWA CHEMICAL CO., LTD.). These thermosetting components may be used individually, or two or more thereof may be used in combination.

In the photosensitive resin composition used in the present invention, a compound having a plurality of isocyanate groups or blocked isocyanate groups in one molecule may also be added. Examples of such compound include polyisocyanate compounds or blocked isocyanate compounds. Here, the term “blocked isocyanate group” refers to a group in which isocyanate group is protected and thus temporarily inactivated by a reaction with a blocking agent. When heated to a prescribed temperature, the blocking agent dissociates to yield an isocyanate group. It has been confirmed that the curability of the photosensitive resin composition and the toughness of the resulting cured product are improved by adding the above-described polyisocyanate compound or blocked isocyanate compound.

As such polyisocyanate compound, for example, an aromatic polyisocyanate, an aliphatic polyisocyanate or an alicyclic polyisocyanate may be employed.

Specific examples of the aromatic polyisocyanate include 4,4′-diphenylmethane diisocyanate, 2,4-tolylene diisocyanate, 2,6-tolylene diisocyanate, naphthalene-1,5-diisocyanate, o-xylylene diisocyanate, m-xylylene diisocyanate and 2,4-tolylene dimer.

Specific examples of the aliphatic polyisocyanate include tetramethylene diisocyanate, hexamethylene diisocyanate, methylene diisocyanate, trimethylhexamethylene diisocyanate, 4,4-methylenebis(cyclohexylisocyanate) and isophorone diisocyanate.

Specific examples of the alicyclic polyisocyanate include bicycloheptane triisocyanate as well as adducts, biurets and isocyanurates of the above-described isocyanate compounds.

As the blocked isocyanate compound, a product obtained by an addition reaction between an isocyanate compound and an isocyanate blocking agent may be employed. Examples of an isocyanate compound which can react with a blocking agent include the above-described polyisocyanate compounds.

Examples of the isocyanate blocking agent include phenolic blocking agents such as phenol, cresol, xylenol, chlorophenol and ethylphenol; lactam-based blocking agents such as ε-caprolactam, δ-valerolactam, γ-butyrolactam and β-propiolactam; activated methylene-based blocking agents such as ethyl acetoacetate and acetylacetone; alcohol-based blocking agents such as methanol, ethanol, propanol, butanol, amyl alcohol, ethylene glycol monomethyl ether, ethylene glycol monoethyl ether, ethylene glycol monobutyl ether, diethylene glycol monomethyl ether, propylene glycol monomethyl ether, benzyl ether, methyl glycolate, butyl glycolate, diacetone alcohol, methyl lactate and ethyl lactate; oxime-based blocking agents such as formaldehyde oxime, acetaldoxime, acetoxime, methylethyl ketoxime, diacetyl monooxime and cyclohexane oxime; mercaptan-based blocking agents such as butylmercaptan, hexylmercaptan, t-butylmercaptan, thiophenol, methylthiophenol and ethylthiophenol; acid amid-based blocking agents such as acetic acid amide and benzamide; imide-based blocking agents such as succinic acid imide and maleic acid imide; amine-based blocking agents such as xylidine, aniline, butylamine and dibutylamine; imidazole-based blocking agents such as imidazole and 2-ethylimidazole; and imine-based blocking agents such as methyleneimine and propyleneimine.

The blocked isocyanate compound may be a commercially available product and examples thereof include SUMIDUR BL-3175, BL-4165, BL-1100 and BL-1265, DESMODUR TPLS-2957, TPLS-2062, TPLS-2078 and TPLS-2117 and DESMOTHERM 2170 and 2265 (all of which are manufactured by Sumika Bayer Urethane Co., Ltd.); CORONATE 2512, CORONATE 2513 and CORONATE 2520 (all of which are manufactured by Nippon Polyurethane Industry Co., Ltd.); B-830, B-815, B-846, B-870, B-874 and B-882 (all of which are manufactured by Mitsui Chemicals, Inc.); and TPA-B80E, 17B-60PX and E402-B8OT (all of which are manufactured by Asahi Kasei Chemicals Corporation). It is noted here that SUMIDUR BL-3175 and BL-4265 are produced by using methylethyl oxime as a blocking agent. The above-described compounds having a plurality of isocyanate groups or blocked isocyanate groups in one molecule may be used individually, or two or more thereof may be used in combination.

The content of such compound having a plurality of isocyanate groups or blocked isocyanate groups in one molecule is preferably 1 to 100 parts by mass with respect to 100 parts by mass of the above-described carboxyl group-containing resin. When the content is less than 1 parts by mass, a coating film having sufficient toughness may not be obtained. Meanwhile, when the content is higher than 100 parts by mass, the storage stability is deteriorated. The content of the compound having a plurality of isocyanate groups or blocked isocyanate groups in one molecule is more preferably 2 to 70 parts by mass.

In cases where a thermosetting component having a plurality of cyclic (thio)ether groups in the molecule is used, it is preferred that a thermosetting catalyst is contained. Examples of the thermosetting catalyst include imidazole derivatives such as imidazole, 2-methylimidazole, 2-ethylimidazole, 2-ethyl-4-methylimidazole, 2-phenylimidazole, 4-phenylimidazole, 1-cyanoethyl-2-phenylimidazole and 1-(2-cyanoethyl)-2-ethyl-4-methylimidazole; amine compounds such as dicyandiamide, benzyldimethylamine, 4-(dimethylamino)-N,N-dimethylbenzylamine, 4-methoxy-N,N-dimethylbenzylamine and 4-methyl-N,N-dimethylbenzylamine; hydrazine compounds such as adipic acid dihydrazide and sebacic acid dihydrazide; and phosphorus compounds such as triphenylphosphine. Further, examples of commercially available thermosetting catalyst include 2MZ-A, 2MZ-OK, 2PHZ, 2P4BHZ and 2P4MHZ (all of which are imidazole-based compounds; trade names), which are manufactured by Shikoku Chemicals Corporation; and U-CAT (registered trademark) 3503N and U-CAT 3502T (both of which are blocked isocyanate compounds of dimethylamine; trade names) and DBU, DBN, U-CAT SA102 and U-CAT 5002 (all of which are a bicyclic amidine compound or a salt thereof), which are manufactured by San-Apro Ltd. The thermosetting catalyst is not particularly restricted to these catalysts and it may be a thermosetting catalyst of an epoxy resin or an oxetane compound, or any compound which facilitates the reaction of at least either of an epoxy group and/or an oxetanyl group with a carboxyl group. These thermosetting catalysts may be used individually, or two or more thereof may be used in combination. Further, a s-triazine derivative, such as guanamine, acetoguanamine, benzoguanamine, melamine, 2,4-diamino-6-methacryloyloxyethyl-s-triazine, 2-vinyl-2,4-diamino-s-triazine, 2-vinyl-4,6-diamino-s-triazine•isocyanuric acid adduct or 2,4-diamino-6-methacryloyloxyethyl-s-triazine•socyanuric acid adduct, may also be used. Preferably, such compound which also functions as an adhesion-imparting agent is used in combination with a thermosetting catalyst.

The content of the thermosetting catalyst is sufficient at an ordinary quantitative ratio and, for example, it is preferably 0.1 to 20 parts by mass, more preferably 0.5 to 15.0 parts by mass, with respect to 100 parts by mass of the above-described carboxyl group-containing resin or the thermosetting component having a plurality of cyclic (thio)ether groups in the molecule.

It is preferred that the photosensitive resin composition used in the present invention contains an inorganic filler. The inorganic filler is used for inhibiting shrinkage on curing of a cured product of the photosensitive resin composition and improving its characteristics such as adhesive property and hardness. Examples of the inorganic filler include barium sulfate, barium titanate, amorphous silica, crystalline silica, Neuburg siliceous earth, molten silica, spherical silica, talc, clay, magnesium carbonate, calcium carbonate, aluminum oxide, aluminum hydroxide, silicon nitride and aluminum nitride.

It is preferred that the above-described inorganic filler have an average particle size of not larger than 5 μm. The content ratio thereof is preferably not higher than 75% by mass, more preferably 0.1 to 60% by mass, based on the total amount of solid contents of the above-described photosensitive resin composition. When the content ratio of the inorganic filler is higher than 75% by mass, the viscosity of the composition may be increased to impair the coating properties and the resulting cured product of the photosensitive resin composition may become fragile.

Furthermore, to the photosensitive resin composition used in the present invention, an elastomer having a functional group may be added. By adding an elastomer having a functional group, the coating properties are improved and the strength of the resulting coating film is also expected to be improved. Examples of the trade name of such elastomer having a functional group include R-45HT and Poly bd HTP-9 (both of which are manufactured by Idemitsu Kosan Co., Ltd.); EPOLEAD PB3600 (manufactured by Daicel Corporation); DENAREX R-45EPT (manufactured by Nagase ChemteX Corporation); and RICON 130, RICON 131, RICON 134, RICON 142, RICON 150, RICON 152, RICON 153, RICON 154, RICON 156, RICON 157, RICON 100, RICON 181, RICON 184, RICON 130MA8, RICON 130MA13, RICON 130MA20, RICON 131MA5, RICON 131MA10, RICON 131MA17, RICON 131MA20, RICON 184MA6 and RICON 156MA17 (all of which are manufactured by Sartomer Co., Inc.). As the elastomer having a functional group, a polyester-based elastomer, a polyurethane-based elastomer, a polyester urethane-based elastomer, a polyamide-based elastomer, a polyester amide-based elastomer, an acrylic elastomer or an olefin-based elastomer can also be employed. In addition, for example, a resin which is obtained by modifying some or all of epoxy groups contained in an epoxy resin having various skeletons with a butadiene-acrylonitrile rubber whose terminals are both modified with carboxylic acid can also be employed. Moreover, for example, an epoxy-containing polybutadiene-based elastomer, an acryl-containing polybutadiene-based elastomer, a hydroxyl group-containing polybutadiene-based elastomer or a hydroxyl group-containing isoprene-based elastomer can also be employed. The appropriate content of the elastomer is preferably in the range of 3 to 124 parts by mass with respect to 100 parts by mass of the above-described carboxyl group-containing resin. Further, the above-described elastomers may be used individually, or two or more thereof may be used in combination.

To the photosensitive resin composition used in the present invention, a mercapto compound may also be added as required. In particular, by adding a mercapto compound to the photosensitive resin composition used to form the photosensitive resin layer on the side which is in contact with the substrate, PCT resistance and HAST resistance are expected to be improved. This is believed to be attributable to an improvement in the adhesive property.

Examples of the mercapto compound include mercaptoethanol, mercaptopropanol, mercaptobutanol, mercaptopropanediol, mercaptobutanediol, hydroxybenzenethiol and derivatives thereof, such as 1-butanethiol, butyl-3-mercaptopropionate, methyl-3-mercaptopropionate, 2,2-(ethylenedioxy)diethanethiol, ethanethiol, 4-methylbenzenethiol, dodecyl mercaptan, propanethiol, butanethiol, pentanethiol, 1-octanethiol, cyclopentanethiol, cyclohexanethiol, thioglycerol and 4,4-thiobisbenzenethiol.

Examples of the commercially available mercapto compound include BMPA, MPM, EHMP, NOMP, MBMP, STMP, TMMP, PEMP, DPMP and TEMPIC (which are manufactured by Sakai Chemical Industry Co., Ltd.); and KARENZ MT-PE1, KARENZ MT-BD1 and KARENZ NR1 (which are manufactured by Showa Denko K.K.).

Further, examples of a mercapto compound having a heterocyclic ring include mercapto-4-butyrolactone (synonym: 2-mercapto-4-butanolide), 2-mercapto-4-methyl-4-butyrolactone, 2-mercapto-4-ethyl-4-butyrolactone, 2-mercapto-4-butyrothiolactone, 2-mercapto-4-butyrolactam, N-methoxy-2-mercapto-4-butyrolactam, N-ethoxy-2-mercapto-4-butyrolactam, N-methyl-2-mercapto-4-butyrolactam, N-ethyl-2-mercapto-4-butyrolactam, N-(2-methoxy)ethyl-2-mercapto-4-butyrolactam, N-(2-ethoxy)ethyl-2-mercapto-4-butyrolactam, 2-mercapto-5-valerolactone, 2-mercapto-5-valerolactam, N-methyl-2-mercapto-5-valerolactam, N-ethyl-2-mercapto-5-valerolactam, N-(2-methoxy)ethyl-2-mercapto-5-valerolactam, N-(2-ethoxy)ethyl-2-mercapto-5-valerolactam, 2-mercaptobenzothiazole, 2-mercapto-5-methylthio-thiadiazole, 2-mercapto-6-hexanolactam, 2,4,6-trimercapto-s-triazine (manufactured by Sankyo Kasei Co., Ltd.: trade name “ZISNET F”), 2-dibutylamino-4,6-dimercapto-s-triazine (manufactured by Sankyo Kasei Co., Ltd.: trade name “ZISNET DB”) and 2-anilino-4,6-dimercapto-s-triazine (manufactured by Sankyo Kasei Co., Ltd.: trade name “ZISNET AF”).

Thereamong, 2-mercaptobenzoimidazole, 2-mercaptobenzoxazole, 2-mercaptobenzothiazole (trade name: ACCEL M; manufactured by Kawaguchi Chemical Industry Co., Ltd.), 3-mercapto-4-methyl-4H-1,2,4-triazole, 5-methyl-1,3,4-thiadiazole-2-thiol and 1-phenyl-5-mercapto-1H-tetrazole are preferred.

The content of such mercapto compound is appropriately 0.01 parts by mass to 10.0 parts by mass, more preferably 0.05 parts by mass to 5 parts by mass, with respect to 100 parts by mass of the above-described carboxyl group-containing resin. When the content is less than 0.01 parts by mass, no improvement in the adhesive property is observed as an effect of adding a mercapto compound, while when the content is higher than 10.0 parts by mass, there may be caused a defect in the development of the photosensitive resin composition and a reduction in the range where drying can be controlled; therefore, such a content of mercapto compound is not preferred. The above-described mercapto compounds may be used individually, or two or more thereof may be used in combination.

To the photosensitive resin composition used in the present invention, as a photosensitive monomer, a compound having an ethylenically unsaturated group in the molecule may be contained. The compound having an ethylenically unsaturated group in the molecule is photo-cured when irradiated with an active energy ray, thereby insolubilizing or assisting to insolubilize the photosensitive resin composition of the present invention to an aqueous alkaline solution. As such a compound, a commonly used and known polyester (meth)acrylate, polyether (meth)acrylate, urethane (meth)acrylate, carbonate (meth)acrylate or epoxy (meth)acrylate may be employed, and specific examples thereof include hydroxyalkyl acrylates such as 2-hydroxyethyl acrylate and 2-hydroxypropyl acrylate; diacrylates of glycol such as ethylene glycol, methoxytetraethylene glycol, polyethylene glycol and propylene glycol; acrylamides such as N,N-dimethylacrylamide, N-methylolacrylamide and N,N-dimethylaminopropylacrylamide; aminoalkyl acrylates such as N,N-dimethylaminoethyl acrylate and N,N-dimethylaminopropyl acrylate; polyhydric alcohols (e.g. hexanediol, trimethylolpropane, pentaerythritol, dipentaerythritol and tris-hydroxyethyl isocyanurate) or polyvalent acrylates (e.g. ethylene oxide adducts, propylene oxide adducts or ε-caprolactone adducts of these polyhydric alcohols); polyvalent acrylates such as phenoxyacrylate, bisphenol A diacrylate and ethylene oxide adducts or propylene oxide adducts of these phenols; and polyvalent acrylates of glycidyl ethers such as glycerin diglycidyl ether, glycerin triglycidyl ether, trimethylolpropane triglycidyl ether and triglycidyl isocyanate. In addition to the above, examples also include acrylates and melamine acrylates that are obtained by direct acrylation or diisocyanate-mediated urethane acrylation of a polyol such as polyether polyol, polycarbonate diol, hydroxyl group-terminated polybutadiene or polyester polyol; and/or methacrylates corresponding to the above-described acrylates.

Further, as the photosensitive monomer, for example, an epoxy acrylate resin which is obtained by allowing a polyfunctional epoxy resin such as a cresol novolac-type epoxy resin to react with acrylic acid or an epoxy urethane acrylate compound which is obtained by allowing the hydroxyl group of the above-described epoxy acrylate resin to react with a hydroxyacrylate such as pentaerythritol triacrylate and a half urethane compound of diisocyanate such as isophorone diisocyanate may also be employed. Such an epoxy acrylate-based resin is capable of improving the photocurability of the photosensitive resin composition without impairing the dryness to touch.

The above-described compounds having an ethylenically unsaturated group in the molecule may be used individually, or two or more thereof may be used in combination. In particular, from the standpoints of photoreactivity and resolution, a compound having 4 to 6 ethylenically unsaturated groups in one molecule is preferred. Further, a compound having two ethylenically unsaturated groups in one molecule is also preferably used since it lowers the linear thermal expansion coefficient of the resulting cured product and reduces the occurrence of peeling during PCT.

The content of the above-described compound having an ethylenically unsaturated group(s) in the molecule is preferably 5 to 100 parts by mass with respect to 100 parts by mass of the above-described carboxyl group-containing resin. When the content is less than 5 parts by mass, the photocurability of the photosensitive resin composition is impaired, so that it may become difficult to form a pattern by development with an alkali after irradiation with an active energy ray. Meanwhile, when the content is higher than 100 parts by mass, the solubility of the photosensitive resin composition to a dilute aqueous alkali solution may be reduced, making the resulting coating film fragile. The content of the above-described compound having an ethylenically unsaturated group(s) in the molecule is more preferably 1 to 70 parts by mass.

Furthermore, the photosensitive resin composition used in the present invention may also contain an organic solvent for the purpose of synthesizing the above-described carboxyl group-containing resin, preparing the composition or adjusting the viscosity thereof for application onto a substrate or a carrier film.

Examples of such an organic solvent include ketones, aromatic hydrocarbons, glycol ethers, glycol ether acetates, esters, alcohols, aliphatic hydrocarbons and petroleum-based solvents. More specific examples thereof include ketones such as methyl ethyl ketone and cyclohexanone; aromatic hydrocarbons such as toluene, xylene and tetramethylbenzene; glycol ethers such as cellosolve, methylcellosolve, butylcellosolve, carbitol, methylcarbitol, butylcarbitol, propylene glycol monomethyl ether, dipropylene glycol monomethyl ether, dipropylene glycol diethyl ether and triethylene glycol monoethyl ether; esters such as ethyl acetate, butyl acetate, dipropylene glycol methyl ether acetate, propylene glycol methyl ether acetate, propylene glycol ethyl ether acetate and propylene glycol butyl ether acetate; alcohols such as ethanol, propanol, ethylene glycol and propylene glycol; aliphatic hydrocarbons such as octane and decane; and petroleum-based solvents such as petroleum ether, petroleum naphtha, hydrogenated petroleum naphtha and solvent naphtha. These organic solvents may be used individually, or two or more thereof may be used in the form of a mixture.

To the photosensitive resin composition used in the present invention, antioxidants such as radical scavengers and peroxide decomposers may be added.

To the photosensitive resin composition used in the present invention, in addition to antioxidants, a known ultraviolet absorbers may also be used.

The photosensitive resin composition used in the present invention may further contain, as required, known additives such as thermal polymerization inhibitors, adhesion-promoting agents, thickening agents (e.g. fine powder silica, organic bentonite and montmorillonite), antifoaming agents (e.g. silicone-based, fluorine-based and macromolecular-based) and/or leveling agents, silane coupling agents (e.g. imidazole-based, thiazole-based and triazole-based) and corrosion inhibitors.

In addition, the photosensitive resin composition used in the present invention may contain flame retardants (e.g. a known phosphorus compound such as phosphinate, phosphate derivative and phosphazene compound). The concentration of elemental phosphorus is preferably in the range of not exceed 3% in the photosensitive resin composition.

### [Laminated Structure]

The laminated structure according to the present invention is a laminated structure comprising: a substrate; and a pattern layer which is formed on the substrate by exposing and developing a photosensitive resin layer of which an absorption coefficient (α) at a wavelength of 365 nm has an increase gradient from a surface of the resin layer toward a surface of the substrate, wherein the pattern layer includes a recessed part having a normal taper structure.

That is, the laminated structure according to the present invention comprises the pattern layer which is formed by exposing and developing the photosensitive resin layer formed by the photosensitive resin composition forming an increase gradient in a Z-axis direction such that the absorption coefficient (α) on the side which is in contact with the substrate at a wavelength of 365 nm comes into higher.

As described in the above, the gradient may be continuous or stepwise. In case of the stepwise gradient, the photosensitive resin layers comprise two or more layers having different absorption coefficients. The continuous and the stepwise gradient can be separately formed by means of applying and drying the photosensitive resin composition.

As described in the above, it is preferred that the photosensitive resin layer of the laminated structure according to the present invention be formed by the photosensitive resin layer constituting the dry film of the present invention.

In the laminated structure according to the present invention, the photosensitive resin layer may also be formed by directly applying the photosensitive resin composition onto a substrate using an appropriate means, such as a blade coater, a lip coater, a comma coater or a film coater, and then drying the resultant. Alternatively, a method in which the first photosensitive resin layer is formed by applying and drying a photosensitive resin composition and then a dry film is laminated on the thus formed first photosensitive resin layer to form the second photosensitive resin layer may also be employed.

Conversely, the laminated structure may also be obtained by laminating a dry film on a substrate to form the first photosensitive resin layer and then applying and drying a photosensitive resin composition on the thus formed first photosensitive resin layer to form the second photosensitive resin layer.

In the photosensitive resin layer of the laminated structure according to the present invention, layered structures in which the absorption coefficient (α) has “a stepwise gradient” and “a continuous gradient” can be separately formed by means of applying a photosensitive resin composition for forming the layered structures. In particular, this is the same case of forming the photosensitive resin layer of the above-described dry film.

In the laminated structure according to the present invention, the total thickness of the photosensitive resin layer is preferably not more than 100 μm, more preferably in the range of 5 to 50 μm. For example, in case of the laminated structure having two photosensitive resin layers, it is preferred that the first photosensitive resin layer (also referred to as L1) having a higher absorption coefficient has a thickness of 1 to 50 μm and the second photosensitive resin layer (also referred to as L2) having a lower absorption coefficient has a thickness of 1 to 50 μm. Here, the thickness ratio of the first photosensitive resin layer (L1) and the second photosensitive resin layer (L2) is preferably in the range of 1:9 to 9:1.

As the above-described substrate, in addition to a printed writing board or flexible printed writing board on which a circuit has been formed in advance, for example, a copper-clad laminate of any grade (for example, FR-4) in which a composite material such as a paper-phenol resin, a paper-epoxy resin, a glass cloth-epoxy resin, a glass-polyimide, a glass cloth/nonwoven fabric-epoxy resin, a glass cloth/paper-epoxy resin, a synthetic fiber-epoxy resin, a fluorocarbon resin-polyethylene-polyphenylene ether composite or a polyphenylene oxide-cyanate ester composite is used, a polyimide film, a PET film, a glass substrate, a ceramic substrate or a wafer substrate can be employed.

The printed writing board according to the present invention is a printed writing board comprising: a substrate; and a pattern layer which is formed on the substrate by exposing and developing a photosensitive resin layer of which an absorption coefficient (α) at a wavelength of 365 nm has an increase gradient from a surface of the resin layer toward a surface of the substrate,
wherein the pattern layer is a solder resist which includes a recessed part having a normal taper structure.

In cases where the laminated structure and the printed writing board according to the present invention are prepared, the photosensitive resin layer formed on the substrate is selectively exposed to an active energy ray through a patterned photomask by a contact method (or a non-contact method) or directly exposed to a pattern using a laser-direct exposure apparatus. Consequently, the exposed parts (the parts irradiated with the active energy ray) of the photosensitive resin layer are cured.

As an exposure apparatus for performing the irradiation with an active energy ray, a direct imaging device (for example, a laser direct imaging device which directly draws an image using a laser based on CAD data transmitted from a computer), an exposure apparatus equipped with a metal halide lamp, an exposure apparatus equipped with an (ultra)high-pressure mercury lamp, an exposure apparatus equipped with LED or an exposure apparatus equipped with a mercury short arc lamp can be employed.

As the active energy ray, it is preferred to use a light having the maximum wavelength in the range of 350 to 410 nm. By using a light having the maximum wavelength in this range, radicals can be efficiently generated from a photopolymerization initiator. Further, although the exposure does is variable depending on the film thickness and the like, it may be set in the range of generally 5 to 500 mJ/cm², preferably 10 to 300 mJ/cm².

As the direct imaging apparatus, for example, those that are manufactured by Orbotech Japan Co., Ltd., RICOH IMAGING COMPANY, LTD., ORC MANUFACTURING CO., LTD. and DAINIPPON SCREEN MFG. CO., LTD. can be employed, and any apparatus may be employed as long as it emits an active energy ray having the maximum wavelength in the range of 350 to 410 nm.

After exposing the photosensitive resin layer to cure the exposed part (the part irradiated with the active energy ray) in the above-described manner, the non-exposed part is developed with a dilute aqueous alkali solution (for example, 0.3 to 3%-by-mass aqueous sodium carbonate solution) to form a cured coating film layer (a pattern).

In this process, as a developing method, for example, a dipping method, a shower method, a spray method or a brushing method may be employed. Further, as a developer, an aqueous alkali solution of potassium hydroxide, sodium hydroxide, sodium carbonate, potassium carbonate, sodium phosphate, sodium silicate, ammonia, amine or the like may be employed.

Further, in cases where the photosensitive resin layer contains a thermosetting component, by heat-curing the resulting film at a temperature of, for example, about 140 to 180° C., a reaction takes place between the carboxylic group of the carboxyl group-containing resin and the thermosetting component having, for example, a plurality of cyclic ether groups and/or cyclic thioether groups in the molecule, so that a cured coating film layer (a pattern) which is excellent in a variety of characteristics such as heat resistance, chemical resistance, resistance to moisture absorption, adhesiveness and electrical property can be formed.

The method of producing the laminated structure according to the present invention is a method of producing a laminated structure comprising: a first process in which a photosensitive resin layer of the above-described dry films is laminated on a substrate such that an absorption coefficient (α) at a wavelength of 365 nm has an increase gradient from a surface of the photosensitive resin layer toward a surface of the substrate; and a second process in which the photosensitive resin layer is exposed and developed to form a pattern layer which includes a recessed part having a normal taper structure.

In the first process, the dry film can be laminated by a known method, and in the second process, a method of exposure and development for forming a pattern layer is employed as mentioned above.

### EXAMPLES

The present invention will now be described concretely by way of examples and comparative examples thereof; however, the present invention is not restricted to the following examples by any means. It is noted here that, in the following Examples and Comparative Examples, “part(s)” and “%” are by mass unless otherwise specified.

### Synthesis Example 1

Into an autoclave equipped with a thermometer, a nitrogen and alkylene oxide introduction device and a stirrer, 119.4 parts of a novolac-type cresol resin (trade name “SHONOL CRG951”, manufactured by Showa Denko K.K., OH equivalent: 119.4), 1.19 parts of potassium hydroxide and 119.4 parts of toluene were loaded. While stirring the resulting mixture, the atmosphere inside the system was replaced with nitrogen and heated. Then, 63.8 parts of propylene oxide was slowly added dropwise and the resultant was allowed to react for 16 hours at a temperature of 125 to 132° C. and a pressure of 0 to 4.8 kg/cm². Thereafter, the system was cooled to room temperature and 1.56 parts of 89% phosphoric acid was added and mixed with the resulting reaction solution to neutralize potassium hydroxide, thereby obtaining a propylene oxide reaction solution of the novolac-type cresol resin having a non-volatile content of 62.1% and a hydroxyl value of 182.2 g/eq. This indicated that an average of 1.08 mol of propylene oxide was added per 1 equivalent of phenolic hydroxyl group.

Into a reaction vessel equipped with a stirrer, a thermometer and an air blowing tube, 293.0 parts of the thus obtained propylene oxide reaction solution of the novolac-type cresol resin, 43.2 parts of acrylic acid, 11.53 parts of methanesulfonic acid, 0.18 parts of methylhydroquinone and 252.9 parts of toluene were loaded. While blowing air into the resulting mixture at a rate of 10 ml/min, the mixture was allowed to react for 12 hours at 110° C. with stirring. By this reaction, 12.6 parts of water was distilled out as an azeotropic mixture with toluene. Thereafter, the resultant was cooled to room temperature and the thus obtained reaction solution was neutralized with 35.35 parts of 15% aqueous sodium hydroxide solution and then washed with water. Subsequently, toluene was replaced with 118.1 parts of diethylene glycol monoethyl ether acetate and distilled out using an evaporator to obtain a novolac-type acrylate resin solution. Next, 332.5 parts of the thus obtained novolac-type acrylate resin solution and 1.22 parts of triphenylphosphine were loaded to a reaction vessel equipped with a stirrer, a thermometer and an air blowing tube. While blowing air to the resulting mixture at a rate of 10 ml/min, 60.8 parts of tetrahydrophthalic anhydride was slowly added with stirring, and the resultant was allowed to react for 6 hours at a temperature of 95 to 101° C. The resulting solution was cooled and then recovered from the reaction vessel. In this manner, a solution of carboxyl group-containing photosensitive resin having a non-volatile content of 65% and a solid acid value of 87.7 mg KOH/g (hereinafter, abbreviated as “A-1”) was obtained.

### Synthesis Example 2

Into a flask equipped with a gas introduction tube, a stirrer, a cooling tube and a thermometer, 330 g of a cresol novolac-type epoxy resin (trade name “EPICLON N-695”, manufactured by DIC Corporation, epoxy equivalent: 220) was loaded, and 340 g of carbitol acetate was added. The resultant was heated and melted, and 0.46 g of hydroquinone and 1.38 g of triphenylphosphine were added. This mixture was heated at a temperature of 95 to 105° C., 108 g of acrylic acid was slowly added dropwise, and the resultant was allowed to react for 16 hours. The product of this reaction was cooled to 80 to 90° C., and 68 g of tetrahydrophthalic anhydride was added. The resultant was allowed to react for 8 hours and then cooled. In this manner, a solution of carboxyl group-containing photosensitive resin having a solid acid value of 50 mg KOH/g and a non-volatile content of 65% (hereinafter, abbreviated as “A-T”) was obtained.

### (Photosensitive Resin Composition Examples (1) to (15))

The resin solutions of the above-described synthesis example were blended with the respective components shown in Table 1 below at the ratios (parts by mass) shown in Table 1. The resultants were each pre-mixed using a stirrer and then kneaded with a 3-roll mill to prepare the photosensitive resin compositions for solder resist.

TABLE 1

| Composition | | Photosetting-Thermosetting Resin Composition Example | | | | | | | |
|---|---|---|---|---|---|---|---|---|---|
| (parts by mass) | | (1) | (2) | (3) | (4) | (5) | (6) | (7) | (8) |
| Carboxyl group- | A-1 | 154 | 154 | 154 | 154 | 154 | | 154 | 154 |
| containing | A-2 | | | | | | 154 | | |
| photosensitive resin | | | | | | | | | |
| Acrylate compound | DPHA *1 | 20 | 20 | 20 | 20 | 20 | 20 | 20 | 20 |
| Epoxy resin | NC-3000 *2 | 30 | 30 | 30 | 30 | 30 | 30 | 30 | 30 |
| | YX-4000 *3 | 20 | 20 | 20 | 20 | 20 | 20 | 20 | 20 |
| Photopolymerization | OXE02 *4 | 0.5 | 1 | | | | | | |
| initiator | TPO *5 | | | 5 | 10 | 15 | 15 | | |
| | Irg127 *6 | | | | | | | 10 | 20 |
| | Irg784 *7 | | | | | | | | |
| | Irg389 *8 | | | | | | | | |
| Filler | Barium | 50 | 50 | 50 | 50 | 50 | 50 | 50 | 50 |
| | sulfate *9 | | | | | | | | |
| | Silica *10 | 20 | 20 | 20 | 20 | 20 | 20 | 20 | 20 |
| | Aktisil AM *11 | 100 | 100 | 100 | 100 | 100 | 100 | 100 | 100 |
| | Hydrotalcite *12 | 10 | 10 | 10 | 10 | 10 | 10 | 10 | 10 |
| Melamine | | 5 | 5 | 5 | 5 | 5 | 5 | 5 | 5 |
| Blue coloring agent *13 | | 0.5 | 0.5 | 0.5 | 0.5 | 0.5 | 0.5 | 0.5 | 0.5 |
| Yellow coloring agent *14 | | 0.5 | 0.5 | 0.5 | 0.5 | 0.5 | 0.5 | 0.5 | 0.5 |
| Absorption | 365 nm | 0.0310 | 0.0353 | 0.0307 | 0.0346 | 0.0383 | 0.0383 | 0.0285 | 0.0301 |
| coefficient (α) | | | | | | | | | |

| Composition | | Photosetting-Thermosetting Resin Composition Example | | | | | | |
|---|---|---|---|---|---|---|---|---|
| (parts by mass) | | (9) | (10) | (11) | (12) | (13) | (14) | (15) |
| Carboxyl group- | A-1 | 154 | 154 | 154 | 154 | 154 | 154 | 154 |
| containing | A-2 | | | | | | | |
| photosensitive resin | 20 | | | | | | | |
| Acrylate compound | DPHA *1 | 20 | 20 | 20 | 20 | 20 | 20 | |
| Epoxy resin | NC-3000 *2 | 30 | 30 | 30 | 30 | 30 | 30 | 30 |
| | YX-4000 *3 | 20 | 20 | 20 | 20 | 20 | 20 | 20 |
| Photopolymerization | OXE02 *4 | | | | | | | |
| initiator | TPO *5 | | | | | | 15 | 15 |
| | Irg127 *6 | | | | | | | |
| | Irg784 *7 | 0.5 | 2 | | | | | |
| | Irg389 *8 | | | 5 | 10 | | | |
| Filler | Barium | 50 | 50 | 50 | 50 | 50 | 50 | 50 |
| | sulfate *9 | | | | | | | |
| | Silica *10 | 20 | 20 | 20 | 20 | 20 | 20 | 20 |
| | Aktisil AM *11 | 100 | 100 | 100 | 100 | 100 | 100 | 100 |
| | Hydrotalcite *12 | 10 | 10 | 10 | 10 | 10 | 10 | 10 |
| Melamine | | 5 | 5 | 5 | 5 | 5 | 5 | 5 |
| Blue coloring agent *13 | | 0.5 | 0.5 | 0.5 | 0.5 | 0.5 | 1 | |
| Yellow coloring agent *14 | | 0.5 | 0.5 | 0.5 | 0.5 | 0.5 | | 1 |
| Absorption | 365 nm | 0.0289 | 0.0354 | 0.0414 | 0.0561 | 0.0089 | 0.0256 | 0.0151 |
| coefficient (α) | | | | | | | | |

In Table 1, the index numbers mean as follows.
*1: dipentaerythritol hexaacrylate (manufactured by Nippon Kayaku Co., Ltd.)
*2: NC-3000 (manufactured by Nippon Kayaku Co., Ltd.); solid content = 60%, solvent (propylene glycol monomethyl ether acetate) = 40%
*3: bixylenol-type epoxy resin (manufactured by Mitsubishi Chemical Corporation)
*4: ethanone, 1-[9-ethyl-6-(2-methylbenzoyl)-9H-carbazole-3-yl]1, 1-(O-acetyloxime) (manufactured by BASF Japan Ltd.)
*5: LUCIRIN TPO (manufactured by BASF Japan Ltd.)
*6: IRGACURE 127 (manufactured by BASF Japan Ltd.)
*7: IRGACURE 784 (manufactured by BASF Japan Ltd.)
*8: IRGACURE 389 (manufactured by BASF Japan Ltd.)
*9: B-30 (manufactured by Sakai Chemical Industry Co., Ltd.)
*10: SO-E2 (manufactured by Admatechs Company Limited.)
*11: manufactured by HOFFMANN MINERAL GmbH (Aktisil AM is the product which a sillitin is aminosilane-coupling-treated, a sillitin is the compound composed of a spherical silica and a lamellar kaolinite.)
*12: DHT-4A (manufactured by Kyowa Chemical Industry Co., Ltd.)
*13: C.I. Pigment Blue 15:3
*14: C.I. Pigment Yellow 147

### (Calculation of Absorption Coefficient (α))

The respective compositions (1) to (15) were applied using an applicator onto a 0.5 mm-thick glass plate at four film thickness levels, and then the absorbance of the resultants at a wavelength of 365 nm was determined by using UV/VIS/NIR spectrometer V-570 (manufactured by JASCO Corporation). An absorption coefficient (α) was calculated from the inclination of the graph plotted with the absorbance on the y-axis and the film thickness on the x in accordance with Beer-Lambert law.

### Examples 1 to 12 and Comparative Examples 1 to 5

### Preparation of Dry Film

Using the above-described photosensitive resin composition examples (1) to (15) in accordance with the combinations shown in Table 2 below, dry films having a patternable multi-layer structure were prepared. The dry film was prepared by repeating the steps of: applying a photosensitive resin composition onto a 38 μm-thick polyester film, which was used as a carrier film, using an applicator; drying the photosensitive resin composition at 80° C. for 10 minutes; applying another photosensitive resin composition thereon; and again drying the resultant at 80° C. for 10 minutes. It is noted here that the application and drying steps of the photosensitive resin compositions were carried out sequentially, starting with the one which was going to be the outermost layer when viewed from the side of the substrate at the time of laminating the resulting dry film onto the substrate.

TABLE 2

| Photosetting- | | | | | | | | | |
|---|---|---|---|---|---|---|---|---|---|
| Thermosetting Resin | Example | | | | | | | | |
| Composition Example | 1 | 2 | 3 | 4 | 5 | 6 | 7 | 8 | 9 |
| (1) | L2 | | | | | | | | L2 |
| | (15 μm) | | | | | | | | (15 μm) |
| (2) | L1 | | | | | | | | L1 |
| | (5 μm) | | | | | | | | (5 μm) |
| (3) | | L2 | L3 | L3 | L3 | L3 | | | |
| | | (15 μm) | (10 μm) | (10 μm) | (20 μm) | (10 μm) | | | |
| (4) | | | L2 | L2 | L2 | L2 | | | |
| | | | (5 μm) | (10 μm) | (10 μm) | (5 μm) | | | |
| (5) | | L1 | L1 | L1 | L1 | | | | |
| | | (5 μm) | (5 μm) | (5 μm) | (10 μm) | | | | |
| (6) | | | | | | L1 | | | |
| | | | | | | (5 μm) | | | |
| (7) | | | | | | | L2 | | |
| | | | | | | | (15 μm) | | |
| (8) | | | | | | | L1 | | |
| | | | | | | | (5 μm) | | |
| (9) | | | | | | | | L2 | |
| | | | | | | | | (15 μm) | |
| (10) | | | | | | | | L1 | |
| | | | | | | | | (5 μm) | |
| (11) | | | | | | | | | |
| (12) | | | | | | | | | |
| (13) | | | | | | | | | L3 |
| | | | | | | | | | (5 μm) |
| (14) | | | | | | | | | |
| (15) | | | | | | | | | |

| Photosetting- | | | | | | | | |
|---|---|---|---|---|---|---|---|---|
| Thermosetting Resin | Example | | | Comparative Example | | | | |
| Composition Example | 10 | 11 | 12 | 1 | 2 | 3 | 4 | 5 |
| (1) | | | | L1 | | | | |
| | | | | (5 μm) | | | | |
| (2) | L1 | | | L2 | | L2 | L1 | |
| | (5 μm) | | | (15 μm) | | (15 μm) | (20 μm) | |
| (3) | L2 | | | | L1 | | | |
| | (15 μm) | | | | (5 μm) | | | |
| (4) | | | | | | | | |
| (5) | | | | | L2 | | | |
| | | | | | (15 μm) | | | |
| (6) | | | | | | | | |
| (7) | | | | | | | | |
| (8) | | | | | | | | |
| (9) | | | | | | | | |
| (10) | | | | | | | | |
| (11) | | L2 | | | | | | |
| | | (15 μm) | | | | | | |
| (12) | | L1 | | | | | | |
| | | (5 μm) | | | | | | |
| (13) | | | | | | L1 | | |
| | | | | | | (5 μm) | | |
| (14) | | | L1 | | | | | L2 |
| | | | (5 μm) | | | | | (15 μm) |
| (15) | | | L2 | | | | | L1 |
| | | | (15 μm) | | | | | (5 μm) |

### (Optimum Exposure Dose)

A single-sided printed writing board having a 15 μm-thick copper circuit formed thereon was prepared and subjected to a pre-treatment using CZ8100 (manufactured by MEC COMPANY LTD.). On the resulting substrate, the above-described dry films of Examples and Comparative Examples were each laminated using a vacuum laminator such that the L1 layer came into contact with the substrate, thereby forming a photosensitive resin layer having a bilayer or three-layer structure on the substrate. Then, the resulting substrate was exposed through a step tablet (Kodak No. 2) using an exposure apparatus equipped with a high-pressure mercury short arc lamp and then developed for 60 seconds (30° C., 0.2 MPa, 1%-by-mass Na₂CO₃ aqueous solution). In this process, the exposure dose at which the pattern of the step tablet remained in three tiers was defined as the optimum exposure does.

### (Characteristic Test)

A single-sided printed writing board having a 15 μm-thick copper circuit formed thereon was prepared and subjected to a pre-treatment using CZ8100 (manufactured by MEC COMPANY LTD.). On the resulting substrate, the above-described dry films of Examples and Comparative Examples were each laminated using a vacuum laminator such that the L1 layer came into contact with the substrate, thereby forming a photosensitive resin layer having a layered structure on the substrate. Then, after exposing the resulting substrate to a solder resist pattern at the above-described optimum exposure dose using an exposure apparatus equipped with a high-pressure mercury short arc lamp, the carrier film was detached and the substrate was developed for 60 seconds with 1%-by-mass aqueous sodium carbonate solution at 30° C. at a spray pressure of 0.2 MPa, thereby obtaining a solder resist pattern. The resulting substrate was irradiated with ultraviolet light at a cumulative exposure dose of 1,000 mJ/cm² in a UV conveyor furnace and then heat-cured at 160° C. for 60 minutes. The characteristics of the thus obtained printed writing board (evaluation substrate) were evaluated in the following manner.

### <Resistance to Electroless Gold Plating>

The evaluation substrates were each plated in a commercially available electroless nickel plating bath and electroless gold plating bath to a nickel thickness of 0.5 μm and a gold thickness of 0.03 μm. After evaluating the presence or absence of infiltration of the plating solution into the solder resist, the presence or absence of detachment of the solder resist was evaluated by performing a tape peeling test. The evaluation criteria were as follows.

∘: Infiltration and detachment were not observed.

Δ: A slight infiltration was observed after the plating; however, no detachment was observed after the tape peeling.

x: The resist layer was detached after the tape peeling.

### <PCT Resistance>

The evaluation substrates subjected to the above-described electroless gold plating were placed in a high-pressure, high-temperature and high-humidity chamber maintained at a temperature of 121° C., a pressure of 2 atm and a humidity of 100% for 300 hours. Thereafter, the change in the condition of each solder resist was evaluated based on the following criteria.

∘: The solder resist did not show any prominent swelling or discoloration.

Δ: No prominent detachment was observed; however, a partial detachment or discoloration was observed.

x: The solder resist showed prominent swelling and discoloration.

### <Resolution>

A negative pattern having a via opening size of 60 μm as a negative mask of evaluation resolution was used to check a cross-sectional shape of a recessed part (an opening part) of a solder resist. Here, in case of an undercut shape, since a detachment or a short might be caused, the solder resist had poor resolution.

The evaluation criteria were as follows.

∘: A normal taper structure

Δ: A reversed taper structure

x: An undercut structure

### (Adhesion)

A solder resist having a pattern with line-and-space 50 μm/100 μm was prepared. The adhesion of the solder resist was evaluated by performing a tape peeling test.

The evaluation criteria were as follows.

∘: No peeling was observed.

Δ: The cracks of the lines were observed.

x: Peeling was observed.

The results of respective tests mentioned above are collectively shown in Table 3.

TABLE 3

| | Example | | | | | | | | | | | | Comparative Example | | | | |
|---|---|---|---|---|---|---|---|---|---|---|---|---|---|---|---|---|---|
| Characteristics | 1 | 2 | 3 | 4 | 5 | 6 | 7 | 8 | 9 | 10 | 11 | 12 | 1 | 2 | 3 | 4 | 5 |
| Optimum Exposure Dose | 150 | 300 | 250 | 250 | 250 | 250 | 600 | 250 | 200 | 150 | 200 | 250 | 150 | 300 | 250 | 100 | 250 |
| (mJ/cm²) | | | | | | | | | | | | | | | | | |
| Resistance to Electroless | ∘ | ∘ | ∘ | ∘ | ∘ | ∘ | ∘ | ∘ | ∘ | ∘ | ∘ | ∘ | Δ | Δ | Δ | ∘ | ∘ |
| Gold Plating | | | | | | | | | | | | | | | | | |
| PCT Resistance | ∘ | ∘ | ∘ | ∘ | ∘ | Δ | ∘ | ∘ | ∘ | ∘ | ∘ | ∘ | Δ | Δ | Δ | Δ | ∘ |
| Resolution | ∘ | ∘ | ∘ | ∘ | ∘ | ∘ | ∘ | ∘ | ∘ | ∘ | ∘ | ∘ | x | x | x | Δ | Δ |
| Adhesion | ∘ | ∘ | ∘ | ∘ | ∘ | ∘ | ∘ | ∘ | ∘ | ∘ | ∘ | ∘ | x | x | x | Δ | x |

### <Elemental Analysis>

A single-sided printed writing board having a 30 μm-thick copper circuit formed thereon was prepared and subjected to a pre-treatment using CZ8100 (manufactured by MEC COMPANY LTD.). On the resulting substrate, the above-described photosensitive dry films of Example 2 and Comparative Example 2 were each laminated using a vacuum laminator such that the L1 layer came into contact with the substrate, thereby forming a resin insulation layer having a layered structure on the substrate. Then, after exposing the resulting substrate to a solder resist pattern at the above-described optimum exposure dose using an exposure apparatus equipped with a high-pressure mercury short arc lamp, the carrier film was detached and the substrate was developed for 60 seconds with 1%-by-mass aqueous sodium carbonate solution at 30° C. at a spray pressure of 0.2 MPa, thereby obtaining a solder resist pattern. The resulting substrate was irradiated with ultraviolet light at a cumulative exposure dose of 1,000 mJ/cm² in a UV conveyor furnace and then heat-cured at 160° C. for 60 minutes.

The resulting substrate was cut and performed elemental analysis of a cross-section.

### DESCRIPTION OF SYMBOLS

1: Cover film
2: Photosensitive resin layer
3: Photosensitive resin layer
4: Carrier film
5: Pattern layer
6: Substrate

1. A dry film comprising:
a film;
and a photosensitive resin layer formed on the film,
wherein the absorption coefficient (α) of said photosensitive resin layer at a wavelength of 365 nm has an increase gradient or a decrease gradient from a surface of said photosensitive resin layer toward a surface of said film.

2. The dry film according to claim 1, wherein the gradient of the absorption coefficient (α) in said photosensitive resin layer is formed by a photopolymerization initiator or a coloring agent.

3. The dry film according to claim 1, wherein the gradient of the absorption coefficient (α) in said photosensitive resin layer is continuous or stepwise.

4. The dry film according to claim 1, wherein said photosensitive resin layer comprises two or more resin layers.

5. The dry film according to claim 1, wherein said photosensitive resin layer comprises a photosensitive resin composition containing a carboxyl group-containing photosensitive resin, a photopolymerization initiator or a coloring agent, a thermosetting component and an inorganic filler.

6. A laminated structure comprising:
a substrate;
and a pattern layer which is formed on the substrate by exposing and developing a photosensitive resin layer of which an absorption coefficient (α) at a wavelength of 365 nm has an increase gradient from a surface of the resin layer toward a surface of said substrate,
wherein said pattern layer includes a recessed part having a normal taper structure.

7. A printed writing board comprising:
a substrate;
and a pattern layer which is formed on the substrate by exposing and developing a photosensitive resin layer of which an absorption coefficient (α) at a wavelength of 365 nm has an increase gradient from a surface of the resin layer toward a surface of said substrate,
wherein said pattern layer is a solder resist which includes a recessed part having a normal taper structure.

8. A method of producing a laminated structure comprising:
a first process in which a photosensitive resin layer, which is included in the dry film according to claim 1, is laminated on a substrate such that an absorption coefficient (α) at a wavelength of 365 nm has an increase gradient from a surface of said photosensitive resin layer toward a surface of said substrate; and
a second process in which said photosensitive resin layer is exposed and developed to form a pattern layer which includes a recessed part having a normal taper structure.

9. The dry film according to claim 2, wherein the gradient of the absorption coefficient (α) in said photosensitive resin layer is continuous or stepwise.

10. The dry film according to claim 2, wherein said photosensitive resin layer comprises two or more resin layers.

11. The dry film according to claim 3, wherein said photosensitive resin layer comprises two or more resin layers.

12. The dry film according to claim 2, wherein said photosensitive resin layer comprises a photosensitive resin composition containing a carboxyl group-containing photosensitive resin, a photopolymerization initiator or a coloring agent, a thermosetting component and an inorganic filler.

13. The dry film according to claim 3, wherein said photosensitive resin layer comprises a photosensitive resin composition containing a carboxyl group-containing photosensitive resin, a photopolymerization initiator or a coloring agent, a thermosetting component and an inorganic filler.

14. The dry film according to claim 4, wherein said photosensitive resin layer comprises a photosensitive resin composition containing a carboxyl group-containing photosensitive resin, a photopolymerization initiator or a coloring agent, a thermosetting component and an inorganic filler.

15. A method of producing a laminated structure comprising:
a first process in which a photosensitive resin layer, which is included in the dry film according to claim 2, is laminated on a substrate such that an absorption coefficient (α) at a wavelength of 365 nm has an increase gradient from a surface of said photosensitive resin layer toward a surface of said substrate; and
a second process in which said photosensitive resin layer is exposed and developed to form a pattern layer which includes a recessed part having a normal taper structure.

16. A method of producing a laminated structure comprising:
a first process in which a photosensitive resin layer, which is included in the dry film according to claim 3, is laminated on a substrate such that an absorption coefficient (α) at a wavelength of 365 nm has an increase gradient from a surface of said photosensitive resin layer toward a surface of said substrate; and
a second process in which said photosensitive resin layer is exposed and developed to form a pattern layer which includes a recessed part having a normal taper structure.

17. A method of producing a laminated structure comprising:
a first process in which a photosensitive resin layer, which is included in the dry film according to claim 4, is laminated on a substrate such that an absorption coefficient (α) at a wavelength of 365 nm has an increase gradient from a surface of said photosensitive resin layer toward a surface of said substrate; and
a second process in which said photosensitive resin layer is exposed and developed to form a pattern layer which includes a recessed part having a normal taper structure.

18. A method of producing a laminated structure comprising:
a first process in which a photosensitive resin layer, which is included in the dry film according to claim 5, is laminated on a substrate such that an absorption coefficient (α) at a wavelength of 365 nm has an increase gradient from a surface of said photosensitive resin layer toward a surface of said substrate; and
a second process in which said photosensitive resin layer is exposed and developed to form a pattern layer which includes a recessed part having a normal taper structure.
